(19) United States
(12) Patent Application Publication
(10) Pub. No.: US 2013/0235538 A1
(43) Pub. Date: Sep. 12, 2013

(54) ELECTRONIC APPARATUS

(71) Applicant: KABUSHIKI KAISHA TOSHIBA, Tokyo (JP)

(72) Inventors: Seiji HASHIMOTO, Ome-shi (JP); Tetsuo OKAZAKI, Hino-shi (JP)

(73) Assignee: KABUSHIKI KAISHA TOSHIBA, Tokyo (JP)

(21) Appl. No.: 13/706,154

(22) Filed: Dec. 5, 2012

(30) Foreign Application Priority Data
Mar. 9, 2012 (JP) 2012-052972

(51) Int. Cl. H05K 5/06

(52) U.S. Cl. CPC H05K 5/06
USPC 361/752

(57) ABSTRACT

According to one embodiment, an electronic apparatus includes a housing, a substrate in the housing, a first member, a second member and an electronic component. The housing includes a wall portion including an opening. The first member is at least partly between the wall portion and the substrate. The second member covers the opening and is pressed to the wall portion by the first member, at least a part of the second member configured to elastically displace. The electronic component on the substrate is configured to be pushed by the displaced part of the second member.

### CROSS-REFERENCE TO RELATED APPLICATIONS

This application is based upon and claims the benefit of priority from prior Japanese Patent Application No. 2012-052972, filed Mar. 9, 2012, the entire contents of which are incorporated herein by reference.

### FIELD

Embodiments described herein relate generally to an electronic apparatus.

### BACKGROUND

An electronic apparatus such as a television receiver has an operation portion, for example, a button. The button is exposed through an opening provided in a housing. A structure to inhibit water infiltration may be provided around the opening.

There is still room for improvement in such an electronic apparatus.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing a television receiver according to a first embodiment;

FIG. 2 is an exemplary sectional view showing a part of a television body according to the first embodiment along the line F2-F2 of FIG. 1;

FIG. 3 is an exemplary plan view showing parts around the sidewall of the television body according to the first embodiment;

FIG. 4 is an exemplary perspective view showing the parts around the sidewall according to the first embodiment from the inside of a housing;

FIG. 5 is an exemplary perspective view showing how to attach a support member according to the first embodiment;

FIG. 6 is an exemplary perspective view showing how to attach a support member according to a second embodiment;

FIG. 7 is an exemplary sectional view showing how to attach a support member according to a third embodiment;

FIG. 8 is an exemplary sectional view showing how to attach a support member according to a fourth embodiment;

FIG. 9 is an exemplary exploded perspective view showing a slate computer according to a fifth embodiment;

FIG. 10 is an exemplary perspective view showing a part of the slate computer according to the fifth embodiment from a side opposite to the side shown in FIG. 9;

FIG. 11 is an exemplary front view showing a television receiver according to a sixth embodiment;

FIG. 12 is an exemplary perspective view showing a display unit shown in FIG. 11;

FIG. 13 is an exemplary exploded perspective view showing the display unit shown in FIG. 11;

FIG. 14 is an exemplary perspective view showing a sealing member shown in FIG. 13;

FIG. 15 is an exemplary sectional view of the display unit shown in FIG. 11;

FIG. 16 is an exemplary sectional view of the display unit shown in FIG. 11;

FIG. 17 is an exemplary plan view showing the inner surface of a base shown in FIG. 13;

FIG. 18 is an exemplary enlarged plan view showing a part of the inner surface of the base shown in FIG. 17;

FIG. 19 is an exemplary perspective view showing the inner surface of a mask shown in FIG. 13;

FIG. 20 is an exemplary enlarged perspective view showing a part of the inner surface of the mask shown in FIG. 19;

FIG. 21 is an exemplary exploded perspective view showing the display unit shown in FIG. 11;

FIG. 22 is an exemplary perspective view showing an attachment structure of a speaker module shown in FIG. 21;

FIG. 23 is an exemplary sectional view showing the attachment structure of the speaker module shown in FIG. 21;

FIG. 24 is an exemplary plan view showing the attachment structure of the speaker module shown in FIG. 21;

FIG. 25 is an exemplary perspective view showing a first position of the speaker module shown in FIG. 21;

FIG. 26 is an exemplary perspective view showing a second position of the speaker module shown in FIG. 21;

FIG. 27 is an exemplary perspective view showing the speaker module shown in FIG. 21;

FIG. 28 is an exemplary chart showing the flow of attaching the speaker module shown in FIG. 21;

FIG. 29 is an exemplary sectional view showing an attachment structure according to the sixth embodiment;

FIG. 30 is an exemplary perspective view showing an electronic apparatus to which the structure according to the sixth embodiment is applicable;

FIG. 31 is an exemplary sectional view showing a first position of a speaker module according to a seventh embodiment;

FIG. 32 is an exemplary sectional view showing a second position of the speaker module according to the seventh embodiment;

FIG. 33 is an exemplary sectional view showing a first position of a speaker module according to an eighth embodiment;

FIG. 34 is an exemplary sectional view showing a second position of the speaker module according to the eighth embodiment;

FIG. 35 is an exemplary plan view showing an attachment structure of a speaker module according to a ninth embodiment; and

FIG. 36 is an exemplary sectional view showing an attachment structure of a press component according to a tenth embodiment.

### DETAILED DESCRIPTION

Various embodiments will be described hereinafter with reference to the accompanying drawings.

In general, according to one embodiment, an electronic apparatus includes a housing, a substrate in the housing, a first member, a second member and an electronic component. The housing includes a wall portion including an opening. The first member is at least partly between the wall portion and the substrate. The second member covers the opening and is pressed to the wall portion by the first member, at least a part of the second member configured to elastically displace. The electronic component on the substrate is configured to be pushed by the displaced part of the second member.

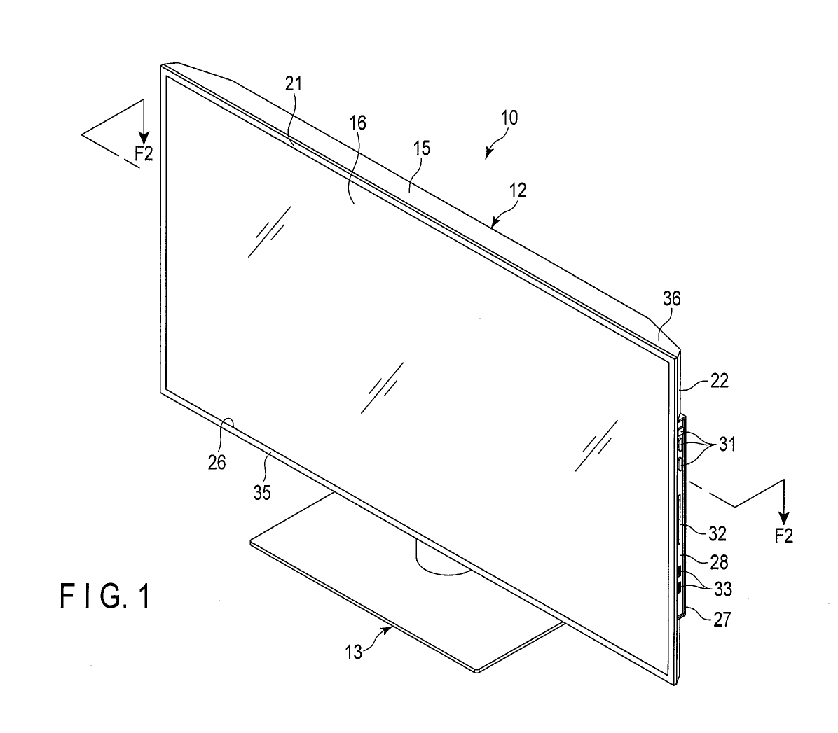

A first embodiment is described below with reference to FIG. 1 to FIG. 5. In the present specification, the proximal side (i.e., user side) is defined as the forward direction, the distal side of the user is defined as the backward direction, the left side of the user is defined as the leftward direction, the right side of the user is defined as the rightward direction, the upper side of the user is defined as the upward direction, and the lower side of the user is defined as the downward direction. Moreover, each element that can be expressed in more than one way may be provided with one or more other examples of expressions. However, this does not deny that an element which is not provided with other expressions may be expressed in different ways, and does not restrict other ways of expressions that are not shown by way of example.

FIG. 1 is an exemplary perspective view showing a television receiver (hereinafter referred to as a “television”) 10. The television 10 is an example of an electronic apparatus. As shown in FIG. 1, the television 10 comprises a television body (television, television receiver, body, display device) 12, and a stand 13. The stand 13 is rotatably coupled to the television body 12. The stand 13 is mounted on a mounting surface (external surface, plane surface, surface) of, for example, a television stand, and supports the television body 12.

The television body 12 comprises a housing (cabinet, external part, wall) 15, and a display module (display device, display unit, electronic component, component) 16. The display module 16 is, for example, a liquid crystal display. The display module 16 is not limited thereto, and may be a plasma display or an organic electroluminescence display. The display module 16 is housed in the housing 15.

The housing 15 has a front surface 21, and a side surface (outer surface, surface, sidewall, wall portion, wall) 22. The side surface 22 is located on the right side of the user. A rectangular display opening 26 is provided in the front surface 21. The display opening 26 exposes the display surface of the display module 16 on which images are displayed.

The side surface 22 is provided to intersect with the front surface 21. The side surface 22 is partly inclined backward from the front surface 21 to approach the center of the television body 12. An interface unit 27 is provided in the side surface 22. The interface unit 27 is formed to project from the side surface 22, and has a sidewall (outer surface, surface, wall portion, wall) 28 which intersects substantially at right angles with the front surface 21. The sidewall 28 is an example of a wall portion.

In the sidewall 28, there are provided a plurality of buttons (switches, components, members, input portions) 31 such as a power button, a channel switch button, and a volume control button, and there are also provided a card aperture 32, and a plurality of terminal openings 33. The buttons 31 are examples of an operation portion and a third member. The card aperture 32 is an opening for inserting a card such as a B-CAS card. The terminal openings 33 are openings for inserting, for example, a USB terminal and an HDMI terminal.

The housing 15 further has a back surface located opposite to the front surface 21, and a lower surface provided to intersect with the front surface 21. For example, a plurality of ventilation holes are provided in the back surface, and the stand 13 is fixed to the back surface. For example, a plurality of speaker openings for producing a sound are provided in the lower surface.

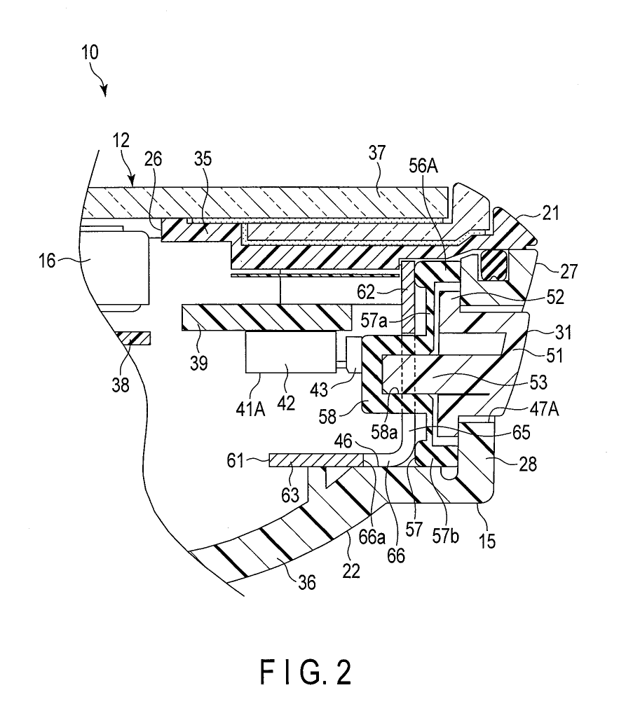

FIG. 2 is an exemplary sectional view showing a part of the television body 12 along the line F2-F2 of FIG. 1. As shown in FIG. 2, the housing 15 has a front cover 35 and a rear cover 36. The front cover 35 and the rear cover 36 are each made of, for example, a resin. The front cover 35 constitutes the front surface 21 of the housing 15. The rear cover 36 constitutes the side surface 22, the back surface, and the lower surface of the housing 15.

A translucent panel 37 is attached to the front surface 21 of the housing 15. The display opening 26 is covered by the panel 37. The display module 16 is exposed to the outside through the panel 37.

A main substrate 38 and a module substrate (circuit board, wiring board, component, unit) 39 are housed in the housing 15. The module substrate 39 is an example of a substrate.

The main substrate 38 is, for example, a rectangular printed circuit board. A plurality of electronic components such as an LSI for image processing are mounted on the main substrate 38. The main substrate 38 is attached to the display module 16, for example, via spacers.

The module substrate 39 is, for example, a printed circuit board. The module substrate 39 is disposed to intersect substantially at right angles with the sidewall 28 and to face the front surface 21. The module substrate 39 is formed into a rectangular shape smaller than the main substrate 38. The module substrate 39 is closer to the sidewall 28 than the main substrate 38. The module substrate 39 is connected to the main substrate 38, for example, by a cable.

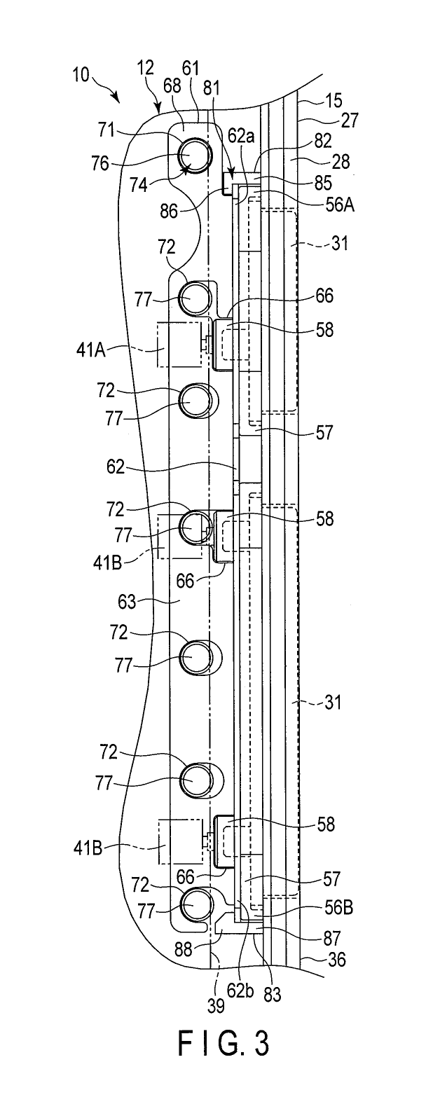

FIG. 3 is an exemplary plan view showing parts around the sidewall 28. As indicated by a two-dot chain line in FIG. 3, for example, a plurality of switches (components) 41A and 41B, a card slot, and a plurality of connectors are mounted on the module substrate 39. The switch 41A is an example of a first electronic component. The two switches 41B are an example of a second electronic component.

The card slot is open to the outside via the card aperture 32, and a card such as a B-CAS card is inserted into the card slot. The connectors are open to the outside via the terminal openings 33, and, for example, a USB terminal and an HDMI terminal are inserted into the connectors.

The switches 41A and 41B are arranged to correspond to the buttons 31. As shown in FIG. 2, each of the switches 41A and 41B comprises a component body (housing, case, fixed portion) 42, and a push portion (end, operated portion, pressure sensor, component) 43. The component body 42 is fixed to the module substrate 39, for example, by soldering. An opening facing the sidewall 28 is provided in the component body 42.

The push portion 43 projects toward the sidewall 28 from the opening of the component body 42. The push portion 43 elastically moves into the component body 42 in response to external pressure. The push portion 43 is partly pushed into the component body 42, and the switches 41A and 41B are thereby operated. In other words, the switches 41A and 41B are operated in response to the pressure on the push portion 43. If the press force on the push portion 43 is removed, the push portion 43 elastically moves back to a predetermined position.

The interface unit 27 has the sidewall 28, and a bottom wall (wall portion, wall, bottom surface, fixing surface, attachment surface) 46 extending in a direction intersecting substantially at right angles with the sidewall 28. The bottom wall 46 faces the front cover 35. The bottom wall 46 is disposed to face at least a part of the module substrate 39.

A plurality of openings (apertures, bores, holes, insertion portions, exposing portions) 47A and 47B are provided in the sidewall 28. The opening 47A is an example of a first opening. The opening 47B is an example of a second opening. The openings 47A and 47B are formed to respectively correspond to the shapes of the buttons 31. For example, the opening 47A corresponding to the button 31 which is the power button is formed into a substantially quadrate shape. The opening 47B corresponding to the button 31 which is the channel switch button or the volume control button is formed into a substantially rectangular shape. The corresponding buttons 31 are respectively inserted through the openings 47A and 47B, and are exposed to the outside of the housing 15.

Each of the buttons 31 has an exposed portion (operation portion, insertion portion, portion) 51, a flange portion (engagement portion, latch portion) 52, and a protrusion (press portion, projecting portion, fit portion, operation portion, portion) 53. The exposed portion 51 is inserted through the corresponding opening 47A or 47B, and is exposed to the outside of the housing 15. The flange portion 52 is provided at the end of the exposed portion 51 located inside the housing 15, and faces the sidewall 28 from the inside of the housing 15. The flange portion 52 is locked to the sidewall 28 from the inside of the housing 15. The protrusion 53 projects into the housing 15 from the exposed portion 51. The tip of the protrusion 53 faces the tip of the push portion 43 of the corresponding switch 41A or 41B. The tip of the protrusion 53 is farther from the sidewall 28 than the flange portion 52.

A plurality of keypads (packing, closing members, members) 56A and 56B are disposed in the housing 15 to correspond to the buttons 31. The keypad 56A is an example of a water infiltration inhibitor and a second member. The keypad 56B is an example of a fourth member. The keypads 56A and 56B are made of, for example, elastic silicon rubber. The keypads 56A and 56B are not limited thereto, and may be made of elastomer or other synthetic rubber. Each of the keypads 56A and 56B has a contact portion 57 and a displacement portion 58 that are formed integrally with each other.

The contact portion 57 is formed to surround the edge of the flange portion 52 of the button 31 and to cover the end of the exposed portion 51 which is provided with the flange portion 52. The contact portion 57 watertightly abuts on the sidewall 28 around the corresponding opening 47A or 47B. The contact portion 57 does not exclusively abut on the sidewall 28 in this way, and may abut on the sidewall 28, for example, in a manner weaker than the watertight condition. The contact portion 57 covers each of the openings 47A and 47B through which the buttons 31 are inserted. In this way, as shown in FIG. 3, the keypad 56A closes the opening 47A, and the keypad 56B closes the opening 47B. The contact portion 57 may cover the openings 47A and 47B.

As shown in FIG. 2, a portion 57a of the contact portion 57 covering the end of the exposed portion 51 is formed to be thinner than the other portion 57b of the contact portion 57 that surrounds the edge of the flange portion 52. That is, the portion 57a covering the end of the exposed portion 51 is more easily deformed than the portion 57b surrounding the edge of the flange portion 52.

The displacement portion 58 is provided to be surrounded by the portion 57a of the contact portion 57. The displacement portion 58 projects into the housing 15 from the portion 57a of the contact portion 57. The displacement portion 58 is provided with a recess 58a facing the button 31. A part of the protrusion 53 of the button 31 is fitted in the recess 58a. The protrusion 53 of the button 31 may be fitted in the recess 58a to be in contact with the side surface of the recess 58a, or may be contained in the recess 58a via a clearance between the protrusion 53 and the side surface of the recess 58a.

The displacement portion 58 is formed to be thicker than the portion 57a of the contact portion 57. If the displacement portion 58 is pressed by the protrusion 53 of the button 31, the displacement portion 58 is elastically displaced. That is, the displacement portion 58 is pressed by the protrusion 53, and the portion 57a of the contact portion 57 surrounding the displacement portion 58 is thereby elastically deformed. As a result, the displacement portion 58 is displaced in a direction in which the displacement portion 58 is pressed by the protrusion 53. Thus, the displacement portion 58 is an example of a part of a displaceable second member.

The displacement portion 58 is located between the protrusion 53 of the button 31 and the push portion 43 of the corresponding switch 41A or 41B. In other words, the protrusion 53 of the button 31 abuts on (faces) the displacement portion 58. Therefore, if the button 31 is pressed, for example, by the user, the protrusion 53 displaces the displacement portion 58, and the displacement portion 58 pushes the push portion 43. That is, if the button 31 is pressed, the switch 41A or 41B is operated in response to the pressure from the displaced displacement portion 58.

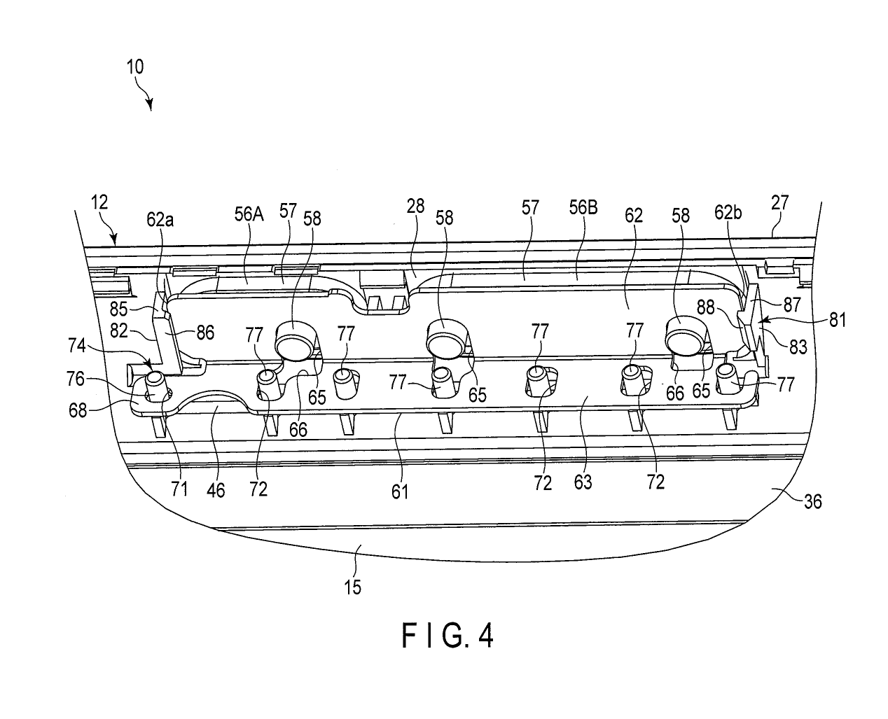

FIG. 4 is an exemplary perspective view showing the parts around the sidewall 28 from the inside of the housing 15. As shown in FIG. 4, a support member (support portion, contact portion, press portion, component, member, part) 61 is disposed inside the housing 15. The support member 61 is an example of a first member. The support member 61 is formed, for example, by a metal plate bent into an L-shape. The support member 61 has a press portion (support portion, contact portion, wall portion, part) 62 and an attachment portion (fixing portion, part) 63 that are formed into a rectangular shape. The press portion 62 is an example of a first portion. The attachment portion 63 is an example of a second portion.

As shown in FIG. 2, at least a part of the press portion 62 is located between the sidewall 28 and the module substrate 39, and faces the sidewall 28. The press portion 62 abuts on (faces) the keypads 56A and 56B, and is in contact with the portion 57b of the contact portion 57. Therefore, as shown in FIG. 3, the contact portions 57 of the keypads 56A and 56B intervene between the sidewall 28 and the press portion 62. In other words, the press portion 62 is closer to the module substrate 39 than the contact portions 57 of the keypads 56A and 56B.

As shown in FIG. 2, the press portion 62 is provided with a plurality of insertion openings (apertures, holes, cutouts, recesses) 65 through which the displacement portions 58 of the keypads 56A and 56B are inserted, respectively. The insertion opening 65 is an example of an insertion portion. As shown in FIG. 4, the insertion openings 65 are arranged in the longitudinal direction of the press portion 62. Each of the insertion openings 65 extends toward the attachment portion 63 from a part corresponding to the displacement portion 58. The displacement portion 58 is configured to be displaced in the insertion opening 65 through which the displacement portion 58 is inserted.

The attachment portion 63 intersects substantially at right angles with the press portion 62, and extends in a direction to depart from the sidewall 28. The attachment portion 63 abuts on the bottom wall 46. A plurality of cutouts 66 are provided in the attachment portion 63. The cutouts 66 are continuous with the insertion openings 65, respectively. As shown in FIG. 2, an edge 66a of the cutout 66 facing the sidewall 28 is farther from the sidewall 28 than the tip of the displacement portion 58 of the keypad 56.

As shown in FIG. 4, an extending portion 68 extends from the attachment portion 63. The extending portion 68 extends in the longitudinal direction of the attachment portion 63 from one end of the longitudinal direction of the attachment portion 63. A circular pivot bore (engaging bore, aperture, recess) 71 is provided in the extending portion 68. The pivot bore 71 is an example of a bore. As shown in FIG. 3, the pivot bore 71 is farther from the center of the attachment portion 63 than one end 62a of the press portion 62 which is close to the extending portion 68.

A plurality of fixing bores 72 are provided in the attachment portion 63. The fixing bores 72 are arranged in the longitudinal direction of the attachment portion 63. Each of the fixing bores 72 is formed into, for example, an elliptical shape extending toward the press portion 62. As shown in FIG. 4, the fixing bores 72 may be continuous with the cutouts 66, or may be cutouts. The fixing bore 72 closest to the extending portion 68 is formed into an elliptical shape shorter than the fixing bore 72 farthest from the extending portion 68.

An engagement portion (hook portion, temporary fastening portion, guide portion) 74 is provided in the bottom wall 46. The engagement portion 74 is an example of an engaging portion. The engagement portion 74 has a plurality of protruding portions (pins, projections, insertion portions) 76 and 77. Each of the protruding portions 76 and 77 protrudes from the bottom wall 46. One protruding portion 76 is inserted through the pivot bore 71. The protruding portions 77 are inserted through the fixing bores 72. In other words, the protruding portions 76 and 77 engage with the pivot bore 71 and the fixing bores 72.

The protruding portions 76 and 77 inserted through the pivot bore 71 and the fixing bores 72 are welded to the attachment portion 63. The attachment portion 63 is thereby fixed to the bottom wall 46. The attachment portion 63 is not exclusively fixed in this way, and may be fixed to the bottom wall 46, for example, by screws.

As shown in FIG. 4, a fixing portion (attachment portion, press portion, part) 81 is provided in the sidewall 28. The fixing portion 81 has a first fit portion 82 and a second fit portion 83. The first and second fit portions 82 and 83 are an example of a pair of fit portions.

As shown in FIG. 3, the first fit portion 82 has a base portion 85 and a claw portion 86. The base portion 85 projects into the housing 15 from the sidewall 28. The base portion 85 abuts on one end 62a of the press portion 62. The claw portion 86 extends from the tip of the base portion 85 toward the second fit portion 83 along the sidewall 28. The contact portion 57 of the keypad 56A and the press portion 62 of the support member 61 are held between the sidewall 28 and the claw portion 86.

The second fit portion 83 has a base portion 87 and a claw portion 88. The base portion 87 projects into the housing 15 from the sidewall 28. The base portion 87 abuts on the other end 62b of the press portion 62. The base portion 87 is elastically deformable. The claw portion 88 extends from the tip of the base portion 87 toward the first fit portion 82 along the sidewall 28. The contact portion 57 of the keypad 56B and the press portion 62 of the support member 61 are held between the sidewall 28 and the claw portion 88.

The press portion 62 is held between the first and second fit portions 82 and 83. The contact portions 57 of the keypads 56A and 56B and the press portion 62 of the support member 61 are held between the sidewall 28 and the claw portions 86 and 88. Thus, the fixing portion 81 fixes the support member 61, and the press portion 62 presses the contact portions 57 of the keypads 56A and 56B to the sidewall 28.

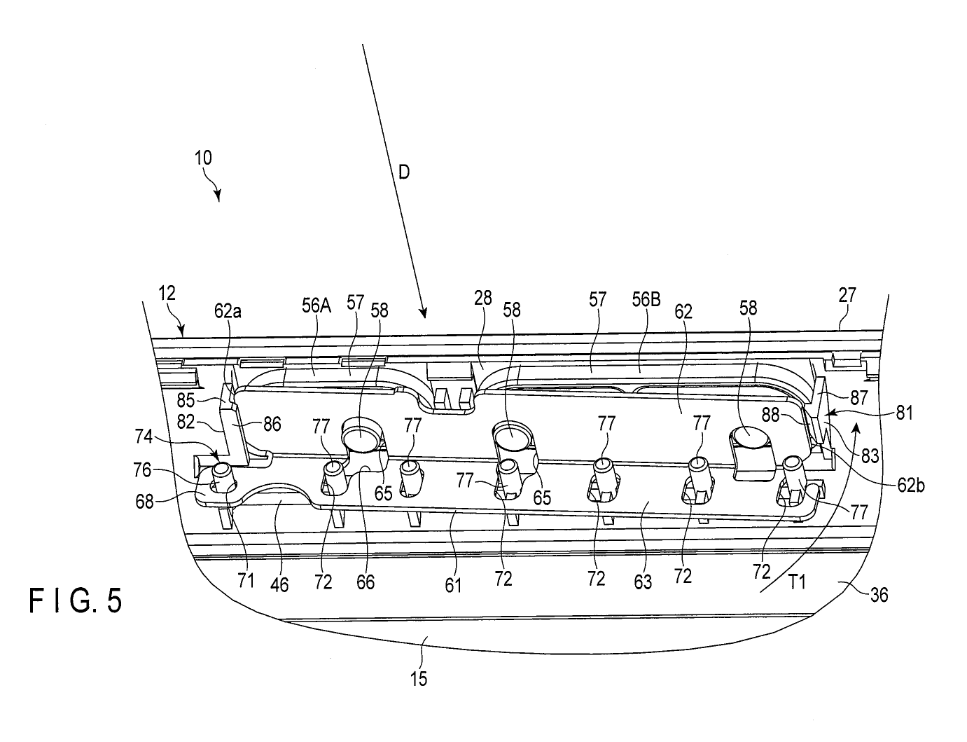

An example of how to attach the support member 61 is described below with reference to FIG. 5. The support member 61 is not exclusively attached in the following way. FIG. 5 is an exemplary perspective view showing how to attach the support member 61.

First, the corresponding keypads 56A and 56B are respectively attached to the buttons 31. That is, the protrusions 53 of the buttons 31 are inserted into the recesses 58a of the displacement portions 58, and the edge of the flange portion 52 is surrounded by the portion 57b of the contact portion 57.

The buttons 31 are then attached to the openings 47A and 47B from the inside of the housing 15, respectively. When the exposed portions 51 of the buttons 31 are inserted through the openings 47A and 47B, the flange portion 52 collides with the sidewall 28. The contact portions 57 of the keypads 56A and 56B attached to the buttons 31 abut on the sidewall 28.

The contact portion 57 of the keypad 56A is located between the sidewall 28 and the claw portion 86 of the first fit portion 82. The contact portion 57 of the keypad 56B is located between the sidewall 28 and the claw portion 88 of the second fit portion 83. Thus, the keypads 56A and 56B are temporarily fastened by the claw portions 86 and 88.

The support member 61 is then attached to the housing 15. As indicated by an arrow D in FIG. 5, the support member 61 is moved substantially perpendicularly to the bottom wall 46. In, other words, the support member 61 is moved closer to the bottom wall 46 from the direction in which the rear cover 36 is open. As a result, the protruding portions 76 and 77 are inserted into the pivot bore 71 and the fixing bores 72 of the support member 61, and the attachment portion 63 collides with the bottom wall 46. At the same time, one end 62a of the press portion 62 is engaged with the first fit portion 82. That is, one end 62a of the press portion 62 is inserted into the space between the sidewall 28 and the claw portion 86.

On the other hand, the other end 62b of the press portion 62 is removed from the second fit portion 83. In other words, the support member 61 is moved closer to the bottom wall 46 at a tilt to the sidewall 28. Therefore, a clearance is made between the press portion 62 and the keypads 56A and 56B.

As the cutouts 66 continuous with the insertion openings 65 are provided in the attachment portion 63, the moving support member 61 avoids the displacement portions 58 of the keypads 56A and 56B. Thus, the support member 61 can be easily moved closer to the bottom wall 46.

As indicated by an arrow T1 in FIG. 5, the support member 61 is then rotated toward the sidewall 28 on the protruding portion 76 inserted through the pivot bore 71. As the fixing bores 72 through which the protruding portions 77 are inserted are formed into an elliptical shape extending toward the press portion 62, the support member 61 is able to rotate. The direction in which the support member 61 rotates is the direction in which the support member 61 intersects with the sidewall 28. That is, the engagement portion 74 engages with the support member 61 rotatably in the direction in which the support member 61 intersects with the sidewall 28.

If the support member 61 is rotated, the end 62b of the press portion 62 climbs over the second fit portion 83. For example, the end 62b of the press portion 62 presses the second fit portion 83, and the base portion 87 of the second fit portion 83 is elastically deformed accordingly. The second fit portion 83 having the elastically deformed base portion 87 avoids the press portion 62, and the end 62b of the rotating press portion 62 collides with the keypad 56B. As a result, the end 62b of the press portion 62 is held between the contact portion 57 of the keypad 56B and the claw portion 88 of the second fit portion 83.

The end 62b of the press portion 62 is fitted into the second fit portion 83 as described above, and the press portion 62 is thereby fixed to the fixing portion 81. As a result, the press portion 62 presses the contact portions 57 of the keypads 56A and 56B to the sidewall 28.

The protruding portions 76 and 77 respectively inserted through the pivot bore 71 and the fixing bore 72 are then welded to the attachment portion 63. As a result, the attachment portion 63 is fixed to the bottom wall 46, and the support member 61 is firmly fixed to the housing 15.

According to the television 10 having the configuration described above, the keypads 56A and 56B covering the openings 47A and 47B are pressed to the sidewall 28 by the support member 61. This can inhibit the infiltration of a liquid such as water or dust into the housing 15.

As the support member 61 presses the keypads 56A and 56B, the position of the module substrate 39 on which the switches 41A and 41B are mounted is free relative to the keypads 56A and 56B. Thus, it is no longer necessary to hold the keypads 56A and 56B with a substrate such as the module substrate 39 or to divide the housing 15 at the position where the openings 47A and 47B are provided. Accordingly, the degree of freedom in the designing of the television 10 is improved.

If the button 31 is pressed by the user, the press force on the button 31 acts on the support member 61. This press force is received by the support member 61, so that damage caused to the module substrate 39 by an external force can be inhibited.

The module substrate 39 is disposed to intersect with the sidewall 28. In other words, the module substrate 39 faces the bottom wall 46. Thus, the module substrate 39 can be attached to the housing 15 substantially in parallel with the bottom wall 46, and the television 10 is more easily assembled.

The insertion openings 65 through which the displacement portions 58 of the keypads 56A and 56B are partly inserted are provided in the press portion 62. Therefore, the displacement portions 58 can press the switches 41A and 41B even if the press portion 62 intervenes between the switches 41A and 41B mounted on the module substrate 39 and the contact portions 57 of the keypads 56A and 56B.

The first and second fit portions 82 and 83 of the fixing portion 81 each have the base portions 85 and 87 and the claw portions 86 and 88. Thus, as screws are needed to fix the support member 61, the number of components of the television 10 and its manufacturing costs can be reduced. Moreover, the support member 61 can be attached to a small space, so that the degree of freedom in the designing is improved, and the television 10 is more easily assembled.

The engagement portion 74 engages with the support member 61 movably in a direction in which the support member 61 intersects with the sidewall 28. This makes it easier to attach the support member 61. Moreover, the buckling of the keypads 56A and 56B can be inhibited during the attachment of the support member 61.

More specifically, if the support member 61 is in contact with the keypads 56A and 56B during the movement of the support member 61 substantially perpendicular to the bottom wall 46, the keypads 56A and 56B are pressed or pulled by the support member 61. However, the support member 61 according to the present embodiment can be moved closer to the bottom wall 46 to make a clearance between the press portion 62 and the keypads 56A and 56B, and then rotated and fixed to the fixing portion 81. This can inhibit the pressing or pulling of the keypads 56A and 56B by the support member 61. Therefore, the buckling of the keypads 56A and 56B can be inhibited.

The pivot bore 71 is provided in the extending portion 68 of the support member 61. The support member 61 is configured to rotate on the protruding portion 76 inserted through the pivot bore 71. This can inhibit shifting during the attachment of the support member 61 to the fixing portion 81.

One support member 61 fixed to the fixing portion 81 presses the keypads 56A and 56B to the sidewall 28. Thus, the number of components and processes can be reduced, and the manufacturing costs can be reduced.

The openings 47A and 47B are provided in the sidewall 28. Therefore, according to the television 10, the buttons 31 with inhibited water infiltration can be provided even in the sidewall of the housing 15. The openings 47A and 47B are not exclusively provided in the sidewall 28, and may be provided in, for example, the bottom wall 46. In this case, the press portion 62 of the support member 61 faces the bottom wall 46, and the attachment portion 63 is attached to, for example, the sidewall 28. That is, the arrangement of the openings 47A and 47B is free, and the degree of freedom in the designing of the television 10 is improved.

When the buttons 31 are attached to the openings 47A and 47B, the keypads 56A and 56B are temporarily fastened by the claw portions 86 and 88 of the first and second fit portions 82 and 83. This makes it easier to assemble the television 10.

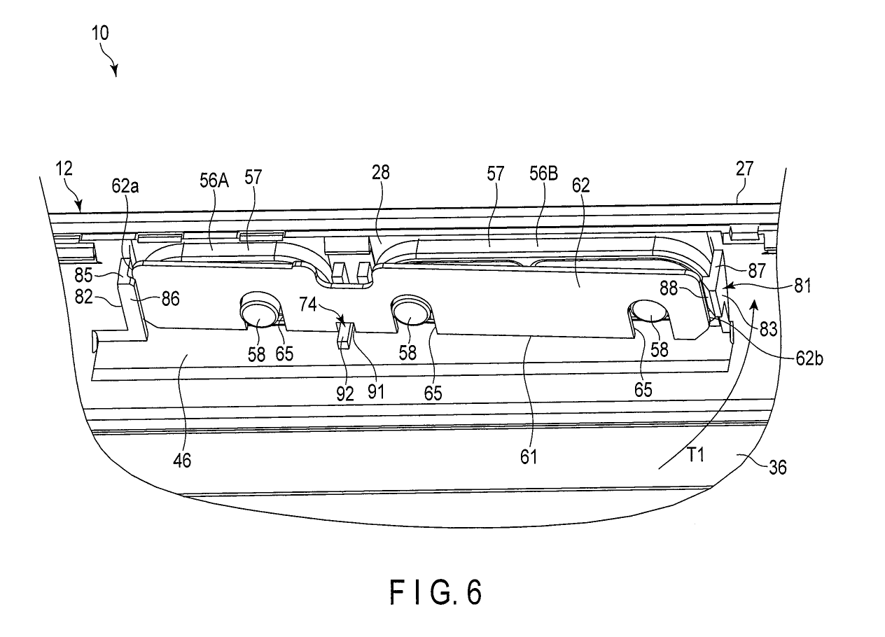

Referring now to FIG. 6, a second embodiment is described. In embodiments disclosed below, components having the same functions as those in the television 10 according to the first embodiment are provided with the same reference numerals. The explanation of these components may be partly or entirely omitted.

FIG. 6 is an exemplary perspective view showing how to attach a support member 61 according to the second embodiment. As shown in FIG. 6, the support member 61 according to the second embodiment is formed by a flat metal plate. A recess (cutout, groove, valley, slit) 91 is formed at the lower end of the support member 61 facing the bottom wall 46.

A protrusion (rib, protruding portion) 92 corresponding to the recess 91 is provided in the bottom wall 46. The protrusion 92 is an example of an engagement portion. The protrusion 92 is a rib provided to extend from the bottom wall 46 to a sidewall 28. The protrusion 92 is engaged with the recess 91 of the support member 61 so that the support member 61 can rotate in a direction intersecting with the sidewall 28.

The support member 61 is attached to a fixing portion 81, for example, in the following way. First, the protrusion 92 is engaged with the recess 91 of the support member 61, and one end 62a of a press portion 62 is fitted into a first fit portion 82. The support member 61 is then rotated on the end 62a of the press portion 62 fitted in the first fit portion 82. The other end 62b of the press portion 62 climbs over a second fit portion 83, and is then held between a claw portion 88 of the second fit portion 83 and a contact portion 57 of a keypad 56B. As a result, the support member 61 is fixed to the fixing portion 81.

According to a television 10 having the configuration described above, the keypads 56A and 56B can be pressed to the sidewall 28 by the support member 61 having a flat plate shape. Thus, the support member 61 can be reduced in size, and the material cost for the television 10 can be reduced. Moreover, a wide space can be kept in a housing 15, and the degree of freedom in the designing is improved.

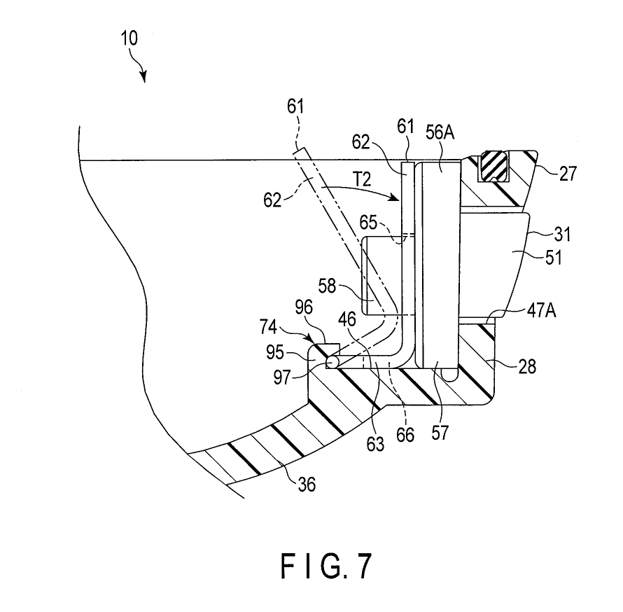

Referring now to FIG. 7, a third embodiment is described. FIG. 7 is an exemplary sectional view showing how to attach a support member 61 according to the third embodiment. As shown in FIG. 7, a pair of engagement portions 74 are provided in a bottom wall 46. The pair of engagement portions 74 each have a base portion 95 projecting from the bottom wall 46, and a claw portion 96 extending from the base portion 95 to a sidewall 28. The pair of engagement portions 74 abut on both longitudinal ends of an attachment portion 63 of the support member 61. In other words, the attachment portion 63 is held between the pair of engagement portions 74.

The attachment portion 63 of the support member 61 has a pair of pivots 97. The pair of pivots 97 are provided, for example, at the end of the attachment portion 63 located apart from a press portion 62. The pair of pivots 97 extend in the longitudinal direction of the attachment portion 63 from both longitudinal ends of the attachment portion 63. The pivots 97 are engaged with the engagement portions 74.

In the present embodiment, both base portions 85 and 87 of first and second fit portions 82 and 83 are elastically deformably formed. That is, the press portion 62 of the support member 61 can climb over a first fit portion 82, and can also climb over a second fit portion 83.

The support member 61 is attached to a fixing portion 81, for example, in the following way. First, the pivots 97 of the attachment portion 63 are engaged with the engagement portions 74. The support member 61 is then rotated on the pivots 97 as indicated by an arrow T2 in FIG. 7. Both ends 62a and 62b of the press portion 62 of the support member 61 climb over the first and second fit portions 82 and 83, respectively. As a result, one end 62a of the press portion 62 is held between a claw portion 86 of the first fit portion 82 and a contact portion 57 of a keypad 56A. The other end 62b of the press portion 62 is also held between a claw portion 88 of the second fit portion 83 and a contact portion 57 of a keypad 56B. Consequently, the support member 61 is fixed to the fixing portion 81.

According to a television 10 having the configuration described above, the support member 61 is rotated on the pivots 97 of the attachment portion 63 engaged with the engagement portions 74 provided in the bottom wall 46. Thus, the support member 61 can be engaged with the engagement portions 74 while the support member 61 is located apart from the keypads 56A and 56B. Therefore, the buckling of the keypads 56A and 56B due to the support member 61 can be inhibited.

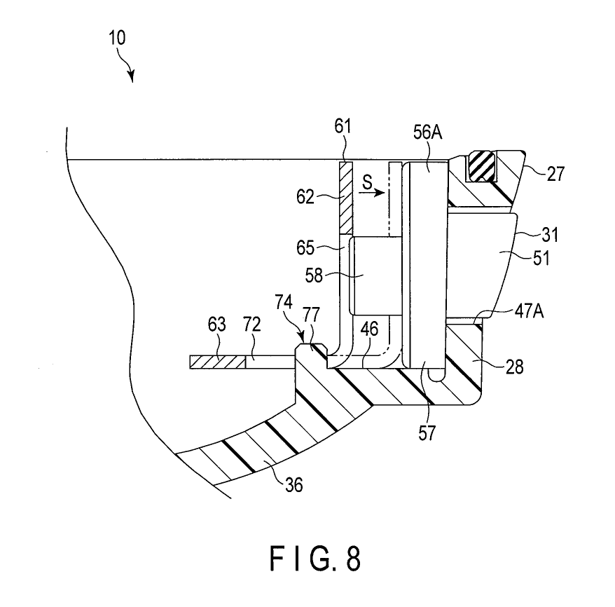

Referring now to FIG. 8, a fourth embodiment is described. FIG. 8 is an exemplary sectional view showing how to attach a support member 61 according to the fourth embodiment. As shown in FIG. 8, an engagement portion 74 is provided in a bottom wall 46. The engagement portion 74 according to the fourth embodiment has a plurality of protruding portions 77. As in the third embodiment, both base portions 85 and 87 of first and second fit portions 82 and 83 are elastically deformable in the present embodiment.

The support member 61 is attached to a fixing portion 81, for example, in the following way. First, the support member 61 is moved substantially perpendicularly to the bottom wall 46 while the support member 61 is located apart from keypads 56A and 56B. As a result, the protruding portions 77 are inserted into fixing bores 72 of the support member 61, and an attachment portion 63 contacts the bottom wall 46.

As indicated by an arrow S in FIG. 8, the support member 61 is then moved in a direction intersecting substantially at right angles with a sidewall 28 along the elliptical fixing bores 72. Both ends 62a and 62b of a press portion 62 of the support member 61 climb over the first and second fit portions 82 and 83, respectively. As a result, one end 62a of the press portion 62 is held between a claw portion 86 of the first fit portion 82 and a contact portion 57 of a keypad 56A. The other end 62b of the press portion 62 is also held between a claw portion 88 of the second fit portion 83 and a contact portion 57 of a keypad 56B. Consequently, the support member 61 is fixed to the fixing portion 81.

According to a television 10 having the configuration described above, the support member 61 is moved in a direction intersecting substantially at right angles with the sidewall 28, and the support member 61 can be thereby fixed to the fixing portion 81. This allows the television 10 to have a simpler configuration, and the manufacturing costs are reduced.

The support member 61 can be moved relative to the bottom wall 46 while the support member 61 is located apart from keypads 56A and 56B. Therefore, the buckling of the keypads 56A and 56B due to the support member 61 can be inhibited.

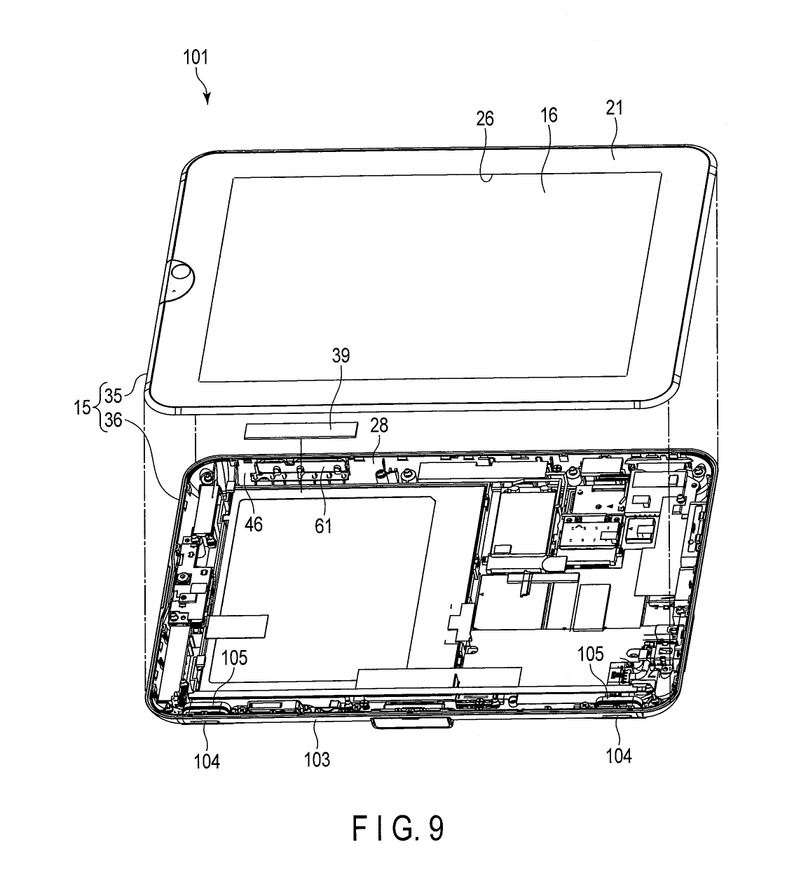

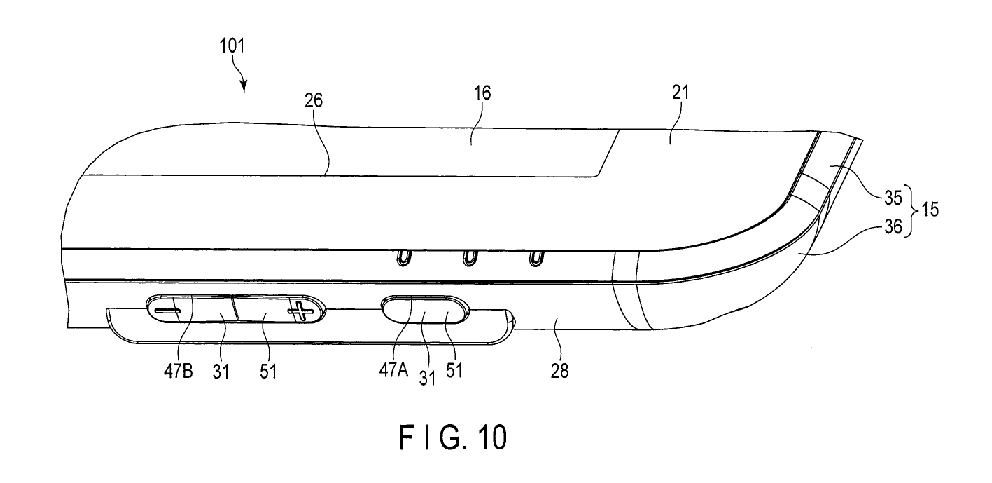

Referring now to FIG. 9 and FIG. 10, a fifth embodiment is described. FIG. 9 is an exemplary exploded perspective view showing a slate computer (personal computer, tablet PC) 101 according to the fifth embodiment. FIG. 10 is an exemplary perspective view showing a part of the slate computer from a side opposite to the side shown in FIG. 9. The slate computer 101 is an example of an electronic apparatus.

As shown in FIG. 9, the slate computer 101 comprises a housing 15. The housing 15 has a front cover 35 that constitutes a front surface 21 of the housing 15, and a rear cover 36. The rear cover 36 has a sidewall 28 that constitutes the side surface of the housing 15, a bottom wall 46 that constitutes the back surface of the housing 15, and the other sidewall 103 that constitutes the other side surface of the housing 15.

As shown in FIG. 10, in the sidewall 28, there are provided a plurality of buttons 31 such as a power button and a volume control button. As in the first embodiment, the buttons 31 are inserted through openings 47A and 47B provided in the sidewall 28, and the openings 47A and 47B are closed by keypads 56A and 56B. The keypads 56A and 56B are pressed to the sidewall 28 by a press portion 62 of the support member 61.

As shown in FIG. 9, the other sidewall 103 is located on the side opposite to the sidewall 28. A plurality of openings 104 are provided in the other sidewall 103. A plurality of speakers 105 are housed in the housing 15 to correspond to the openings 104. The speakers 105 are in collision with the other sidewall 103 from the inside of the housing 15, and close the corresponding openings 104.

According to the slate computer 101 having the configuration described above, the keypads 56A and 56B covering the openings 47A and 47B are pressed to the sidewall 28 by the support member 61, as in the first embodiment. This can inhibit the infiltration of a liquid such as water or dust into the housing 15.

The position of a module substrate 39 on which switches 41A and 41B pushed by a displacement portion 58 of the keypads 56A and 56B are mounted is free relative to the keypads 56A and 56B. Thus, it is no longer necessary to hold the keypads 56A and 56B with a substrate such as the module substrate 39 or to divide the housing 15 at the position where the openings 47A and 47B are provided. Accordingly, the degree of freedom in the designing of the slate computer 101 is improved.

As described above, the electronic apparatus is not limited to the television 10 or the slate computer 101, and may be a different kind of electronic apparatus such as a portable computer, a personal digital assistant (PDA), a cellular phone, or a smartphone.

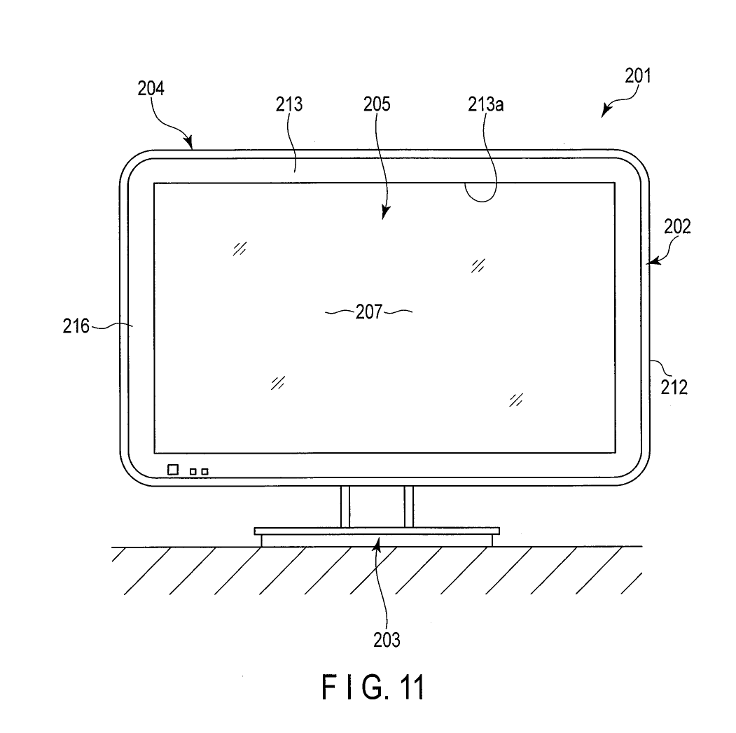

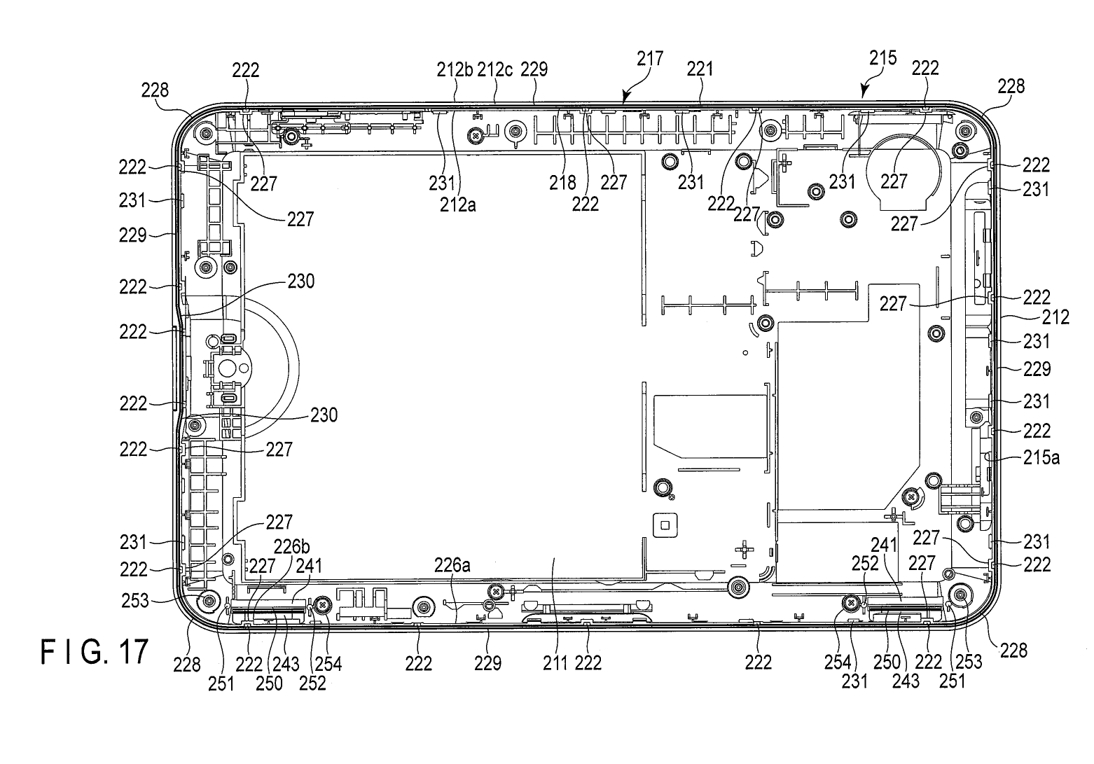

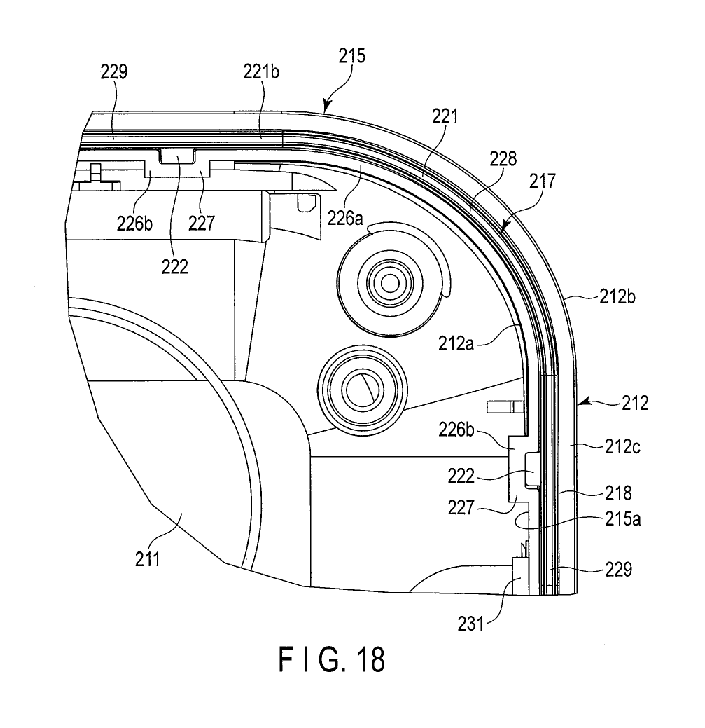

Referring now to FIG. 11 to FIG. 28, a sixth embodiment is described. FIG. 11 to FIG. 28 disclose a television receiver 201 according to the sixth embodiment. The television receiver 201 is an example of the “electronic apparatus”. The structures according to the present embodiment and the following embodiments are not limited to the television receiver, and may be widely applicable to various kinds of electronic apparatuses including a notebook type portable computer (notebook PC), a slate type portable computer (slate. PC, tablet), a mobile telephone (including a smartphone), and a game machine.

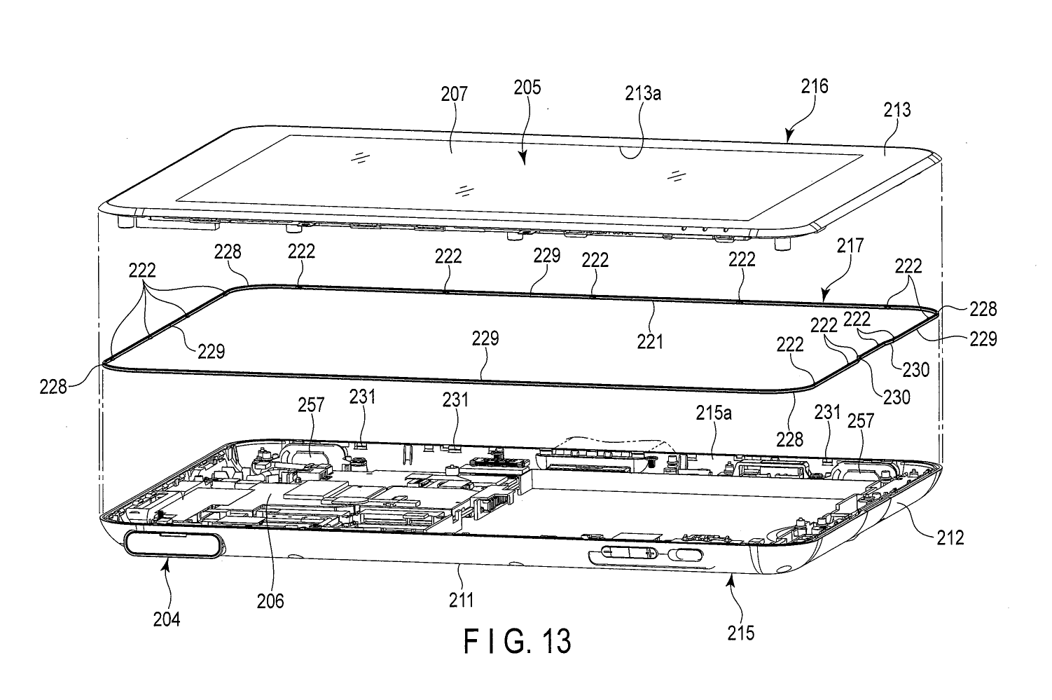

As shown in FIG. 11, the television receiver 201 has a display unit 202 (main unit), and a stand 203 (support portion) which supports the display unit 202. The display unit 202 has a housing 204. A display 205 and a circuit board 206 (see FIG. 13) are housed in the housing 204.

The display 205 has a first surface 205a (display surface) including a display screen 207, and a second surface 205b (back surface) located on the side opposite to the first surface 205a. A touch sensor (touch panel) is provided in the first surface 205a. The touch sensor is an example of an input portion (input receiving portion, operation portion).

As shown in FIG. 11 to FIG. 13, the housing 204 is formed into a flat box shape having a first wall 211 (rear wall), a second wall 212 (peripheral wall, sidewall), and a third wall 213 (front wall). The first wall 211 extends substantially parallel with (expands substantially parallel with) the display 205 and the circuit board 206. The first wall 211 faces the second surface 205b of the display 205 and the circuit board 206.

The third wall 213 is located on the side opposite to the first wall 211. The third wall 213 extends substantially parallel with (expands substantially parallel with) the first wall 211. The third wall 213 faces the first surface 205a of the display 205. The display 205 is located between the first wall 211 and the third wall 213.

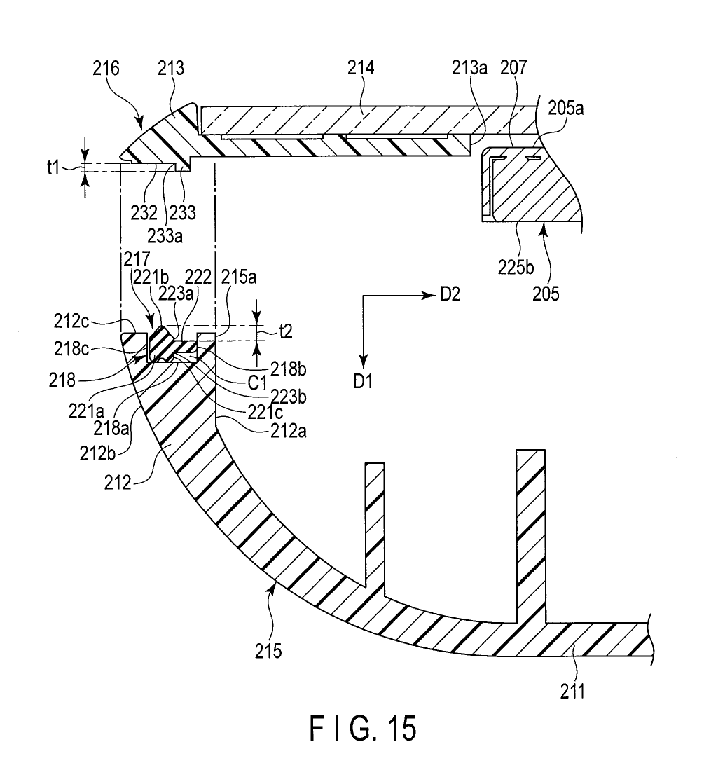

The third wall 213 is provided with an opening 213a which exposes the display screen 207. For example, a translucent panel 214 is provided in the third wall 213 (see FIG. 15). The panel 214 is, for example, a glass member or a plastic member. The panel 214 is supported by the third wall 213, and covers the opening 213a. The display screen 207 is exposed to the outside through the panel 214.

The second wall 212 extends in a direction intersecting with the first wall 211 and the third wall 213. The second wall 212 extends in the thickness direction of the housing 204, and ranges between the end (peripheral end, peripheral edge) of the first wall 211 and the end (peripheral end, peripheral edge) of the third wall 213. The second wall 212 is provided, for example, all around the first wall 211 and the third wall 213. The thickness direction of the housing 204 is the direction traveling from the first wall 211 to the third wall 213 (or from the third wall 213 to the first wall 211).

As shown in FIG. 13 to FIG. 15, the third wall 213 is larger than the first wall 211. Therefore, the second wall 212 is arc-shaped to link the end of the first wall 211 to the end of the third wall 213. The second wall 212 has a curved surface (surface, outer surface) bulging out of the housing 204. The second wall 212 expands out of the housing 204 from the first wall 211 toward the third wall 213.

As shown in FIG. 13, the housing 204 has a base 215 (lower cover, first cover, first housing member, first member), and a mask 216 (upper cover, second cover, second housing member, second member). The base 215 includes the first wall 211 and the second wall 212. The mask 216 includes the third wall 213. The housing 204 is configured by attaching the mask 216 to the base 215.

The base 215 is tray-shaped, and is open in a direction intersecting with the first wall 211 (in the thickness direction of the housing 204, on the side opposite to the first wall 211). The inner peripheral surface (later-described inner surface 212a) of the second wall 212 defines an opening 215a which exposes the inside of the base 215 to the outside.

As shown in FIG. 13, in the assembly of the display unit 202, the first wall 211 of the base 215 is placed on an external mounting surface (e.g., an assembly table), components are attached to the inside of the base 215, and the mask 216 is attached to the base 215. Therefore, the first wall 211 may be referred to as a “lower wall” or “bottom wall”. The third wall 213 may be referred to as an “upper wall”. Hereinafter, the first wall 211 is referred to as the bottom wall 211, the second wall 212 is referred to as the sidewall 212, and the third wall 213 is referred to as the upper wall 213, for convenience of explanation.

The television receiver 201 according to the present embodiment is, for example, waterproof. Therefore, the television receiver 201 has various structures shown below to make it waterproof. These structures are not exclusively provided for waterproofing, and may be provided for other purposes.

(Sealing Structure of Housing)

First, a sealing structure of the housing 204 is described. As shown in FIG. 13, a sealing member 217 (elastic portion, elastic member, intervening member, closing member, packing, member, component) is provided between the base 215 and the mask 216. One example of the sealing member 217 is a gasket (case gasket). The sealing member 217 is made of, for example, rubber. The sealing member 217 is held (compressed, deformed) between the base 215 and the mask 216, and liquid-tightly closes the space between the base 215 and the mask 216.

More specifically, as shown in FIG. 13 to FIG. 15, the sidewall 212 of the housing 204 has the inner surface 212a (inner peripheral surface, first surface), an outer surface 212b (surface, outer peripheral surface, second surface), and an attachment surface 212c (connecting surface, support surface, third surface). The inner surface 212a is exposed inside the housing 204. The outer surface 212b is located on the side opposite to the inner surface 212a, and is exposed outside the housing 204.

The attachment surface 212c extends in a direction intersecting with the inner surface 212a and the outer surface 212b, and ranges between the inner surface 212a and the outer surface 212b. The attachment surface 212c is substantially parallel with the bottom wall 211. The attachment surface 212c faces the end (peripheral end, peripheral edge) of the mask 216. That is, the attachment surface 212c faces the end of the mask 216 in a direction intersecting with (e.g., in a direction intersecting substantially at right angles with) the bottom wall 211. The attachment surface 212c abuts on the end of the mask 216, and supports the end of the mask 216.

The attachment surface 212c is provided, for example, all around the base 215. A groove 218 (attachment portion, support portion, holding portion, storing portion, engagement portion, recess) to which the sealing member 217 is attached is provided in the attachment surface 212c. The groove 218 faces the end of the mask 216, and is covered by the mask 216. The groove 218 is provided, for example, all around the base 215, and is formed into a looped shape (frame shape) along the peripheral end (peripheral edge) of the base 215. The groove 218 is located outside the opening 215a, and surrounds the opening 215a.

As shown in FIG. 15, the groove 218 has a bottom surface 218a (support surface, attachment surface, far portion, first surface), a first side surface 218b (first upright surface, first peripheral surface, second surface), and a second side surface 218c (second upright surface, second peripheral surface, third surface). The bottom surface 218a is substantially parallel with the attachment surface 212c. The bottom surface 218a has a first end, and a second end located on the side opposite to the first end. The first side surface 218b stands from the first end of the bottom surface 218a, and links the first end of the bottom surface 218a to the attachment surface 212c. The second side surface 218c stands from the second end of the bottom surface 218a, and links the second end of the bottom surface 218a to the attachment surface 212c.

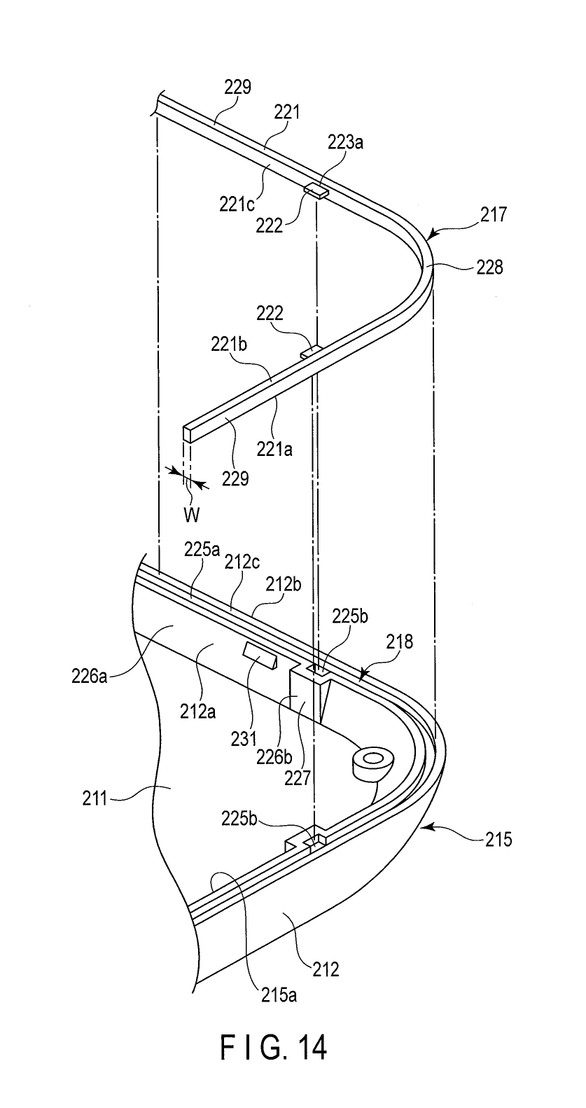

As shown in FIG. 13 and FIG. 14, the sealing member 217 has a shape corresponding to the groove 218. That is, the sealing member 217 is formed into a looped shape (frame shape) along the peripheral end (peripheral edge) of the base 215. The sealing member 217 is attached to the groove 218. The sealing member 217 is located outside the opening 215a, and surrounds the opening 215a.

As shown in FIG. 13 to FIG. 15, the sealing member 217 has a packing portion 221 (intervening portion, closing portion, blocking portion, compressing portion, first portion), and a plurality of projecting portions 222 (protrusions, jaws, projected portion, support portion, second portion). The packing portion 221 extends linearly. The packing portion 221 constitutes the main part of the sealing member 217, and is formed into a looped shape (frame shape) along the peripheral end of the base 215.

The packing portion 221 is located outside the opening 215a, and surrounds the opening 215a. The packing portion 221 is held between the base 215 and the mask 216, and is compressed (compressively deformed) between the base 215 and the mask 216. The packing portion 221 liquid-tightly closes the space between the base 215 and the mask 216.

As shown in FIG. 15, the packing portion 221 has a section closer to a pentagonal shape than a circular shape. The packing portion 221 has a first end 221a and a second end 221b in the thickness direction of the packing portion 221. The first end 221a faces the bottom surface 218a of the groove 218, and abuts on the bottom surface 218a of the groove 218. The second end 221b is located on the side opposite to the first end 221a. The second end 221b faces the mask 216, and abuts on the mask 216.

As shown in FIG. 15, the first end 221a has two protruded portions, and a recess provided therebetween. The two protruded portions abut on the bottom surface 218a of the groove 218, and are supported by the bottom surface 218a of the groove 218. As the recess is provided between the two protruded portions, the two protruded portions are apt to be elastically deformed. Therefore, the first end 221a is apt to tightly contact (closely contact) the bottom surface 218a of the groove 218. This enhances the liquid-tightness (waterproof property) of the television receiver 201.

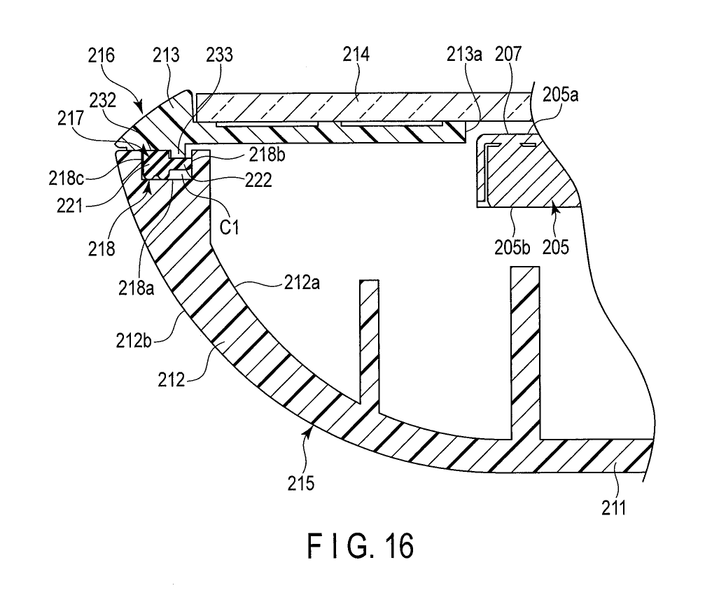

The second end 221b is wedge-shaped (V-shaped) when not compressively deformed. That is, the second end 221b is thinner in parts closer to the mask 216. As shown in FIG. 16, the second end 221b abuts on the mask 216, and is supported by the mask 216. The second end 221b is pressed by the mask 216, and is deformed (elastically deformed) along the inner surface of the mask 216. This ensures that the space between the second end 221b and the mask 216 is liquid-tightly closed. Here, the second end 221b is wedge-shaped and is therefore apt to be elastically deformed. Therefore, the second end 221b is apt to tightly contact (closely contact) the mask 216. This enhances the liquid-tightness (waterproof property) of the television receiver 201.

As shown in FIG. 13 and FIG. 14, the projecting portions 222 are partly provided in the packing portion 221. The projecting portions 222 are distant from one another in the extending direction of the packing portion 221 (in the circumferential direction of the packing portion 221).

As shown in FIG. 15, the packing portion 221 has a side surface 221c (inner peripheral surface, inner surface) ranging between the first end 221a and the second end 221b. The side surface 221c faces the first side surface 218b of the groove 218. The projecting portions 222 are provided in the side surface 221c, and project into the packing portion 221 from the side surface 221c. The projecting portions 222 extend in the shape of a plate in a direction substantially parallel with the bottom surface 218a of the groove 218.

Here, the direction in which the mask 216 is attached to the base 215 (the thickness direction of the housing 204) is defined as a first direction D1. The direction intersecting with the first direction D1 (e.g., the direction intersecting substantially at right angles with the first direction D1) is defined as a second direction D2. The projecting portions 222 project in the second direction D2.

As shown in FIG. 15, the projecting portion 222 projects substantially from the center of the side surface 221c. A first step 223a is provided between the projecting portion 222 and the second end 221b. Therefore, the projecting portion 222 is located closer to the bottom surface 218a of the groove 218 than the second end 221b. The projecting portion 222 is located closer to the first end 221a than the second end 221b. In other words, the projecting portion 222 is farther from the attachment surface 212c (the mask 216) than the second end 221b.

A second step 223b is provided between the projecting portion 222 and the first end 221a. Therefore, the projecting portion 222 is located closer to the mask 216 than the first end 221a. The projecting portion 222 is located closer to the second end 221b than the first end 221a. In other words, the projecting portion 222 is farther from the bottom surface 218a of the groove 218 than the first end 221a. A clearance C1 is provided between the projecting portion 222 and the bottom surface 218a of the groove 218.

If the sealing member 217 (the packing portion 221) is twisted or collapsed during the attachment of the sealing member 217 to the groove 218, the projecting portion 222 abuts on the bottom surface 218a of the groove 218. This inhibits the considerable twisting or collapse of the sealing member 217 (the packing portion 221).

As shown in FIG. 14, the groove 218 has a first portion 225a, and a second portion 225b. The first portion 225a is provided to adapt to the outer shape of the packing portion 221, and the packing portion 221 is received in the first portion 225a. The second portion 225b corresponds to the projecting portion 222. The second portion 225b is provided to adapt to the outer shape of the projecting portion 222, and the projecting portion 222 is received in the second portion 225b. The bottom surface 218a of the groove 218 located in the second portion 225b is an example of a “first portion facing the projecting portion”.

The sidewall 212 has a first region 226a (first portion) and a second region 226b (second portion). The first region 226a corresponds to a part where the projecting portions 222 are not provided. The first region 226a extends substantially parallel with the packing portion 221. The second region 226b corresponds to the projecting portion 222. The second region 226b has a raised portion 227 (projected portion, projecting portion) projecting into the housing 204 as compared with the first region 226a. Thus, the attachment surface 212c of the second region 226b is wider than the attachment surface 212c of the first region 226a. The second portion 225b of the groove 218 is provided in the wider attachment surface 212c of the second region 226b.

As shown in FIG. 13, the packing portion 221 has four corners 228 (corner portions, arc-shaped portions, curved portions), and four linear portions 229 extending between the four corners 228. The packing portion 221 also has a bent portion 230 bent toward the inside of the housing 204 along one linear portion 229.

The corner 228 and the bent portion 230 are each an example of a path changing portion (nonlinear portion) which is changed from the linear shape of the packing portion 221. The projecting portions 222 are separately located on both sides of the path changing portion. In other words, the path changing portion is located between the projecting portions 222. Some of the projecting portions 222 are provided in the linear portion 229. The projecting portions 222 may be provided along the corner 228 or along the bent portion 230.

As shown in FIG. 14, an engagement portion 231 (receiving portion, claw portion, support portion, attachment portion) with which the mask 216 engages is provided in the inner surface 212a of the sidewall 212. The projecting portion 222 is provided, for example, in the vicinity of the engagement portion 231. The engagement portion 231 is provided in the first region 226a of the sidewall 212 (i.e., the region where the raised portion 227 is not present).

The engagement portion 231 is aligned with the raised portion 227 in a direction substantially parallel with the inner surface 212a of the sidewall 212 (in a direction along the inner surface 212a). In other words, a part of the engagement portion 231 is located closer to the outer surface 212b of the sidewall 212 than a part of the raised portion 227. The engagement portion 231 and the raised portion 227 are provided in different regions of the sidewall 212, so that the sidewall 212 can be reduced in thickness. This contributes to the size reduction of the television receiver 201.

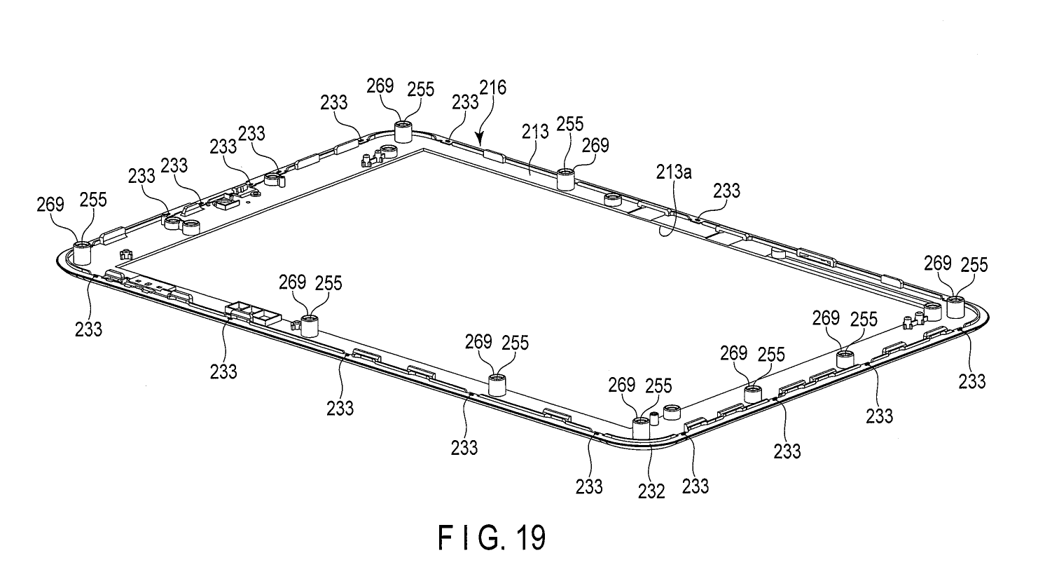

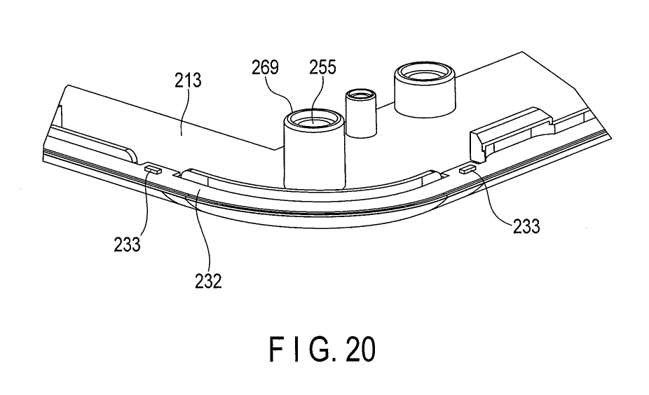

As shown in FIG. 15, FIG. 16, FIG. 19, and FIG. 20, the inner surface of the mask 216 has a flat portion 232 (press portion, contact portion, connecting portion, first portion), and a plurality of support portions 233 (protrusions, projecting portions, support portions, second portions). The flat portion 232 is provided all around the mask 216. The flat portion 232 faces the packing portion 221, and contacts the packing portion 221. The flat portion 232 presses the packing portion 221 toward the bottom surface 218a of the groove 218, and supports the packing portion 221. Consequently, the packing portion 221 is compressed between the flat portion 232 and the bottom surface 218a of the groove 218.

The support portions 233 are partly provided at the positions corresponding to the projecting portions 222 of the sealing member 217. The support portions 233 are provided separately in the circumferential direction of the peripheral end of the mask 216. The support portions 233 are, for example, protrusions (ribs) provided on the inner surface of the mask 216. The support portions 233 project toward the projecting portions 222 from the mask 216, and face the projecting portions 222. The support portions 233 face the projecting portions 222 from the side opposite to the bottom surface 218a of the groove 218. The support portion 233 is an example of a “second portion facing the projecting portion”. The tip of the support portion 233 comes into the groove 218, and faces the projecting portion 222 within the groove 218.

As shown in FIG. 15, a third step 233a is provided between the support portion 233 and the flat portion 232. The step width t1 (thickness) of the third step 233a is smaller than the step width t2 (thickness) of the first step 223a of the sealing member 217.

As shown in FIG. 16, the support portion 233 is slightly distant from the projecting portion 222 or lightly abuts on the projecting portion 222. The support portions 233 face the projecting portions 222 to regulate the twisting or collapse of the sealing member 217 (the packing portion 221). That is, the sealing member 217 may be twisted or collapsed, and the projecting portions 222 may move in a direction to depart from the bottom surface 218a of the groove 218. In this case, the support portions 233 hold the projecting portions 222 and inhibit the twisting or collapse of the sealing member 217 (the packing portion 221). The support portions 233 inhibit the twisting or collapse of the sealing member 217 (the packing portion 221) caused between the mask 216 and the base 215 during the attachment of the mask 216 to the base 215.

According to such a configuration, the assembly of the electronic apparatus can be improved.

The sealing member intervening between the base and the mask is crushed (compressively deformed) between the mask and the base during the attachment of the mask to the base. This ensures the liquid-tightness between the mask and the base.

Here, when the mask is attached straight down to the base, the sealing member is not easily twisted or collapsed. However, the mask may be obliquely attached to the base due to an error in the assembly or the skill level of an operator. In this case, the sealing member is easily twisted or collapsed between the mask and the base. If the sealing member is twisted or collapsed, the sealing member may not be properly crushed between the mask and the base, and the sealing member may not be able to fulfill its function.

Thus, in the present embodiment, the sealing member 217 of the television receiver 201 has the packing portion 221, and the projecting portions 222 partly provided in the packing portion 221. The base 215 has a first portion (e.g., the bottom surface 218a of the groove 218) facing the projecting portion 222. The mask 216 has a second portion (e.g., the support portion 233) facing the projecting portion 222 from the side opposite to the first portion. According to such a configuration, the projecting portion 222 is supported by the base 215 and the mask 216, and the packing portion 221 is not easily rotated. This makes it possible to inhibit the twisting or collapse of the sealing member 217 and improve the assembly of the television receiver 201.

Additionally, the above-mentioned support portions 233 are provided so that the sealing member 217 is not easily twisted or collapsed even if the width W (breadth) of the packing portion 221 (see FIG. 14) is reduced. Therefore, the sealing member 217 having the small width W can be used. This contributes to the size reduction of the television receiver 201.

In the present embodiment, the mask 216 has the support portions 233 facing the projecting portions 222 from the side opposite to the base 215. According to such a configuration, the projecting portions 222 are supported by the support portions 233, and the turning of the packing portion 221 is regulated. This can inhibit the twisting or collapse of the sealing member 217.

In the present embodiment, the projecting portions 222 are provided on the inner side of the looped packing portion 221. Therefore, the raised portion 227 is substantially aligned with the engagement portion 231 along the inner surface 212a of the sidewall 212. Thus, the television receiver 201 can be reduced in size.

In the present embodiment, the clearance C1 is provided between the projecting portion 222 and the bottom surface 218a of the groove 218. According to such a configuration, it is possible to avoid the situation in which the packing portion 221 is not sufficiently compressed between the mask 216 and the base 215 because of the obstructive projecting portion 222 which is held between the mask 216 and the base 215. That is, this facilitates the proper compression of the packing portion 221 between the mask 216 and the base 215 by providing the clearance C1 (allowance, margin) between the projecting portion 222 and the bottom surface 218a of the groove 218.

In the present embodiment, the projecting portion 222 is located closer to the bottom surface 218a of the groove 218 than the second end 221b of the packing portion 221. That is, the first step 223a is provided between the second end 221b of the packing portion 221 and the projecting portion 222. According to such a configuration, it is possible to further avoid the situation in which the packing portion 221 is not sufficiently compressed between the mask 216 and the base 215 because of the obstructive projecting portion 222 which is held between the flat portion 232 of the mask 216 and the base 215.

In the present embodiment, the tip of the support portion 233 comes into the groove 218, and faces the projecting portion 222 within the groove 218. Such a configuration further ensures that the support portions 233 hold the projecting portions 222 when the sealing member 217 is twisted or collapsed.

In the present embodiment, the second end 221b of the packing portion 221 is wedge-shaped and becomes thinner in parts closer to the mask 216. Such a shape allows the second end 221b to be easily elastically deformed, and allows the second end 221b and the mask 216 to easily come into close contact.

On the other hand, if the second end 221b is wedge-shaped, the sealing member 217 is apt to be twisted or collapsed when the mask 216 is obliquely attached to the base 215. However, according to the configuration in the present embodiment, the projecting portions 222 can be supported by the support portions 233 to inhibit the twisting or collapse of the sealing member 217. In other words, as the projecting portions 222 and the support portions 233 are provided, the twisting or collapse is inhibited, and at the same time, the second end 221b is wedge-shaped so that the mask 216 and the packing portion 221 can be in closer contact.

In the present embodiment, the projecting portions 222 are separately located on both sides of the path changing portion of the packing portion 221. Such a configuration further ensures that the path changing portion which is particularly apt to be twisted or collapsed can be supported. Moreover, the projecting portions 222 are provided on both sides of the path changing portion of the packing portion 221 rather than along the path changing portion, so that a housing structure such as a boss can be provided in the vicinity of the path changing portion (e.g., the corner 228). This contributes to the size reduction of the television receiver 201.

In the present embodiment, the projecting portions 222 and the support portions 233 are partly provided at the peripheral end of the base 215. Thus, the engagement portion 231 (coupling portion) of the base 215 and the mask 216 can be provided by using the region (e.g., the first region 226a) in which the projecting portions 222 and the support portions 233 are not provided. Consequently, according to the configuration in the present embodiment, it is possible to reduce the television receiver 201 in size as compared with the case where the projecting portions 222 and the support portions 233 are provided all around the peripheral end of the base 215.

The television receiver 201 is not limited to the configuration described above. For example, the sealing member 217 may be attached to the mask 216 instead of the base 215. That is, the groove 218 may be provided in the mask 216 to attach the sealing member 217, and the support portions 233 may be provided in the base 215. In this case, the mask 216 is an example of a “first member”. The base 215 is an example of a “second member”. The attachment portion to attach the sealing member 217 does not have to be a groove. The sealing member 217 is not limited to the looped shape.

The projecting portion 222 does not exclusively extend in a direction substantially parallel with the bottom surface 218a of the groove 218. The projecting portion 222 may extend, for example, in a direction intersecting with the bottom surface 218a. The projecting portions 222 may otherwise project outward from the outer peripheral surface of the packing portion 221. The packing portion 221, the projecting portion 222, and the support portion 233 are not limited to the shapes and structures described above.

(Speaker Attachment Structure)

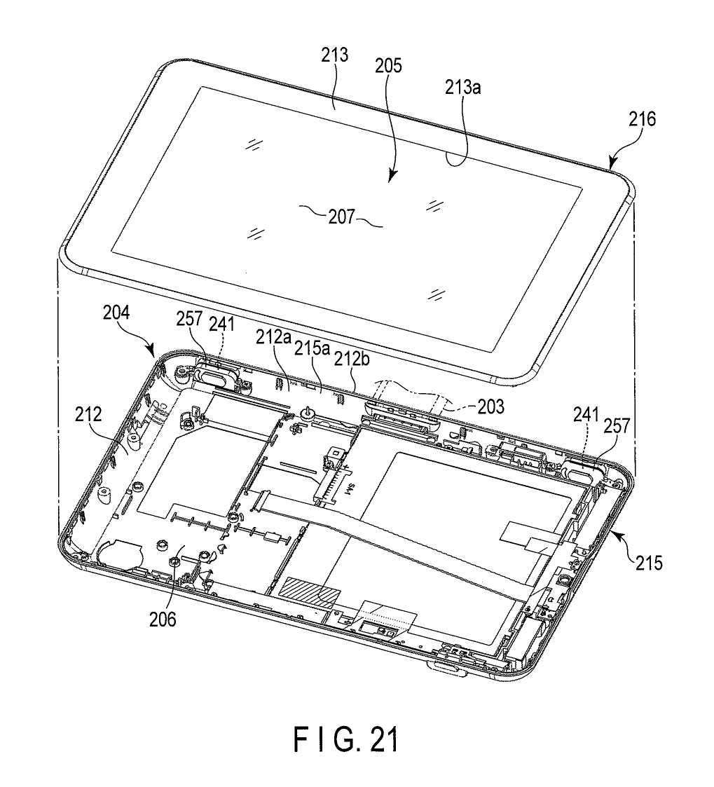

Now, a speaker attachment structure is described. As shown in FIG. 21, a pair of speakers 241 are housed in the housing 204. As the attachment structures for the pair of speakers 241 are substantially the same, the attachment structure for one speaker 241 is described in detail by way of example.

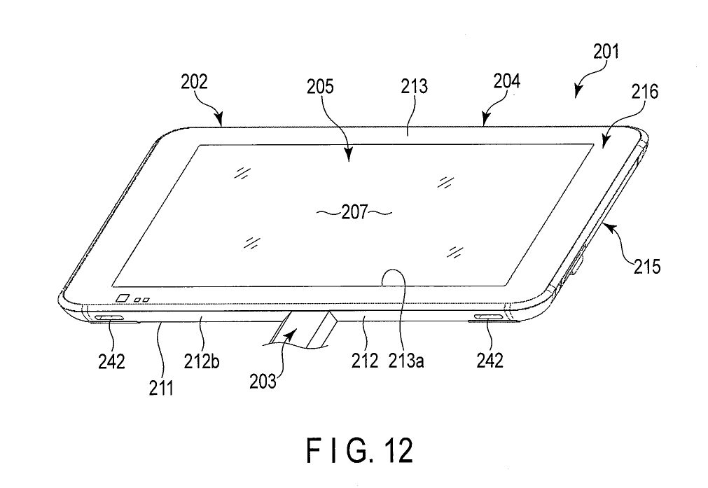

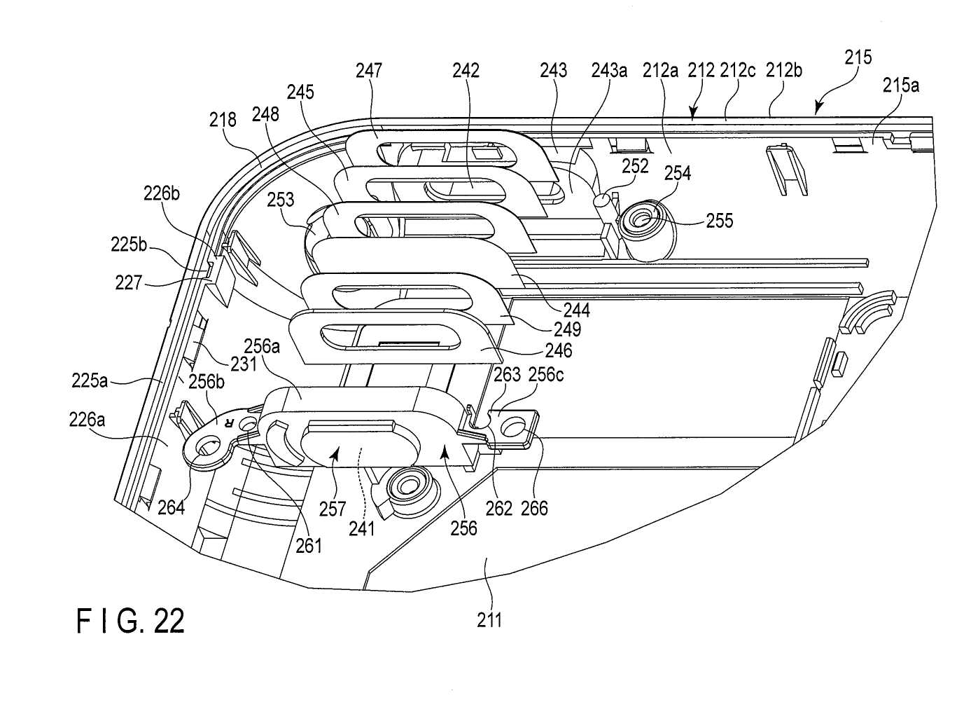

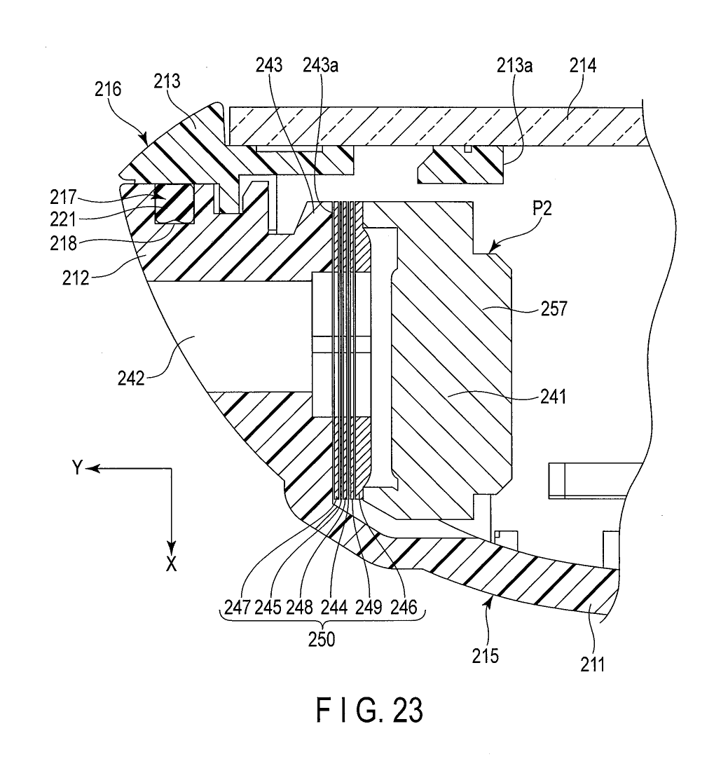

As shown in FIG. 12, FIG. 22, and FIG. 23, an opening 242 is provided in the sidewall 212 of the housing 204. The opening 242 is a sound release portion (sound release opening) through which the sound from the speaker 241 is released. The opening 242 is provided substantially parallel with the bottom wall 211, and laterally passes through the sidewall 212. As shown in FIG. 21 to FIG. 23, the speaker 241 faces the opening 242 within the housing 204.

An attachment portion 243 (raised portion) to which the speaker 241 is attached is provided in the inner surface 212a of the sidewall 212 of the housing 204. The attachment portion 243 projects to the inside of the housing 204 from the inner surface 212a of the sidewall 212. Thus, the attachment portion 243 has an attachment surface 243a extending in the thickness direction of the housing 204. That is, the attachment surface 243a extends in a direction perpendicular to the arc-shaped sidewall 212. The opening 242 (sound release opening) is provided in the attachment portion 243 integrally with the sidewall 212.

As shown in FIG. 22 and FIG. 23, a waterproof sheet 244, two cushions 245 and 246, and three double-sided tapes 247, 248 and 249 are provided in the space between the speaker 241 and the opening 242 (the sidewall 212). The waterproof sheet 244 (liquid-tight sheet, waterproof portion, blocking portion, shielding portion, sheet, member) is located between the attachment surface 243a and the speaker 241. No hole is provided in the waterproof sheet 244. The waterproof sheet 244 is made of, for example, a relatively rigid material to transmit the vibration from the speaker 241 to the outside.

The first cushion 245 (first elastic portion, first intervening member) is provided between the waterproof sheet 244 and the attachment surface 243a. The second cushion 246 (second elastic portion, second intervening member) is provided between the waterproof sheet 244 and the speaker 241. The cushions 245 and 246 are members that can be deformed when pressed, and are, for example, sponge members or rubber members. The cushions are provided on both sides of the waterproof sheet 244 so that the waterproof sheet 244 can vibrate back and forth. Openings corresponding to the openings 242 (sound release openings) are provided in the first and second cushions 245 and 246, respectively.

The waterproof first double-sided tape 247 is provided between the first cushion 245 and the attachment surface 243a. The waterproof second double-sided tape 248 is provided between the first cushion 245 and the waterproof sheet 244. The third double-sided tape 249 is provided between the waterproof sheet 244 and the second cushion 246. Openings corresponding to the openings 242 (sound release openings) are provided in the first to third double-sided tapes 247, 248 and 249, respectively.

The waterproof sheet 244, the cushions 245 and 246, and the double-sided tapes 247, 248 and 249 are bonded together, and attached to the attachment surface 243a before the attachment of the speaker 241, and then supported by the housing 204. The waterproof sheet 244, the cushions 245 and 246, and the double-sided tapes 247, 248 and 249 that are bonded together as one constitute an example of a sealing portion 250. The sealing portion 250 is an example of an “elastic portion”.

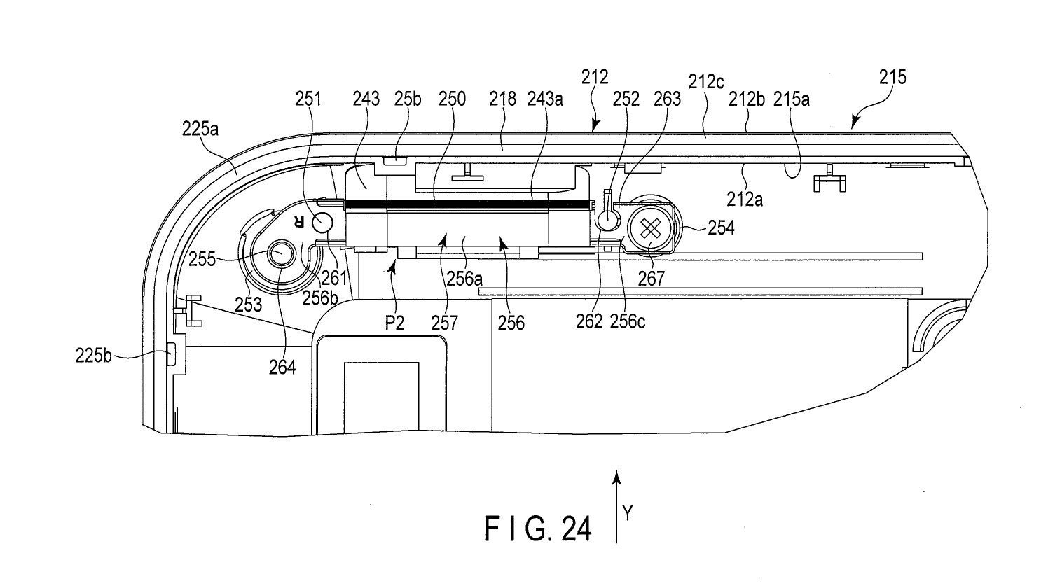

As shown in FIG. 24 to FIG. 26, the housing 204 has a first support portion 251 (first protrusion, first attachment portion, first temporary fastening portion, first temporary fixing portion) and a second support portion 252 (second protrusion, second attachment portion, second temporary fastening portion, second temporary fixing portion). Each of the first and second support portions 251 and 252 is a protrusion projecting from the inner surface of the housing 204, and is, for example, a columnar pin. The first support portion 251 and the second support portion 252 are, for example, separately located on both sides of the attachment portion 243 (the opening 242).

The first support portion 251 and the second support portion 252 project in a direction intersecting with the bottom wall 211 (e.g., in a direction intersecting substantially at right angles with the bottom wall 211). The first support portion 251 and the second support portion 252 project, for example, substantially parallel with the attachment surface 243a. In the present embodiment, the first support portion 251 and the second support portion 252 project in a direction intersecting substantially at right angles with the bottom wall 211 (i.e., the thickness direction of the housing 204). The first support portion 251 and the second support portion 252 may otherwise project in a direction diagonally intersecting with the bottom wall 211. A component (module, unit) can engage with the first support portion 251 from a direction intersecting with the bottom wall 211 (e.g., from a direction intersecting substantially at right angles with the bottom wall 211).

As shown in FIG. 24 to FIG. 26, the housing 204 has a first fixing portion 253 and a second fixing portion 254. Each of the first and second fixing portions 253 and 254 is a protruded portion projecting from the inner surface of the housing 204, and is, for example, a boss. A hole 255 is provided in each of the first and second fixing portions 253 and 254. The hole 255 is, for example, a threaded hole or a threaded through-hole. The hole 255 may be a hole with a bottom or may be a through-hole. The hole 255 is open in a direction intersecting with the bottom wall 211 (e.g., in a direction intersecting substantially at right angles with the bottom wall 211).

The first fixing portion 253 is located in the vicinity of the first support portion 251. The first support portion 251 is located between the first fixing portion 253 and the attachment portion 243. The second fixing portion 254 is located in the vicinity of the second support portion 252. The second support portion 252 is located between the second fixing portion 254 and the attachment portion 243. The first support portion 251 may be located outside the first fixing portion 253. The second support portion 252 may be located outside the second fixing portion 254.

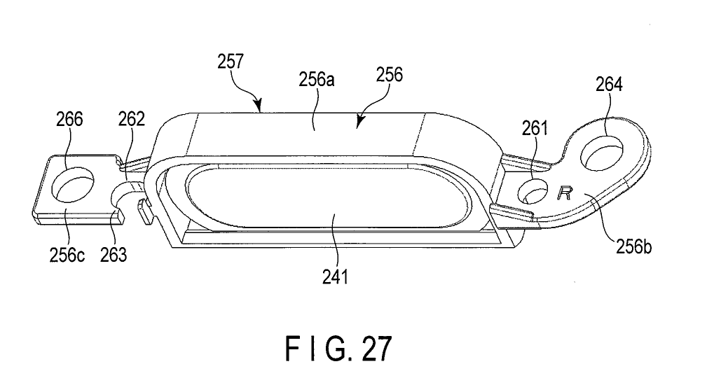

As shown in FIG. 27, a holder 256 (speaker holder, holding portion, case, attachment member) is attached to the speaker 241. The holder 256 and the speaker 241 are integrated as a speaker module 257 (speaker unit). The housing 204 (the base 215) is an example of a “first member”. The speaker module 257 is an example of a “second member”, a “module”, a “unit”, a “component”, or a “member”.

As shown in FIG. 24 to FIG. 27, the holder 256 has a first portion 256a, a second portion 256b, and a third portion 256c. The first portion 256a is a holding portion (support portion) which holds the speaker 241. The first portion 256a surrounds the outer shape of the speaker 241. The first portion 256a faces the sealing portion 250 (elastic portion).

The first portion 256a has a first end, and a second end located on the side opposite to the first end. The second portion 256b is provided at the first end of the first portion 256a, and extends in a direction to depart from the speaker 241. The third portion 256c is provided at the second end of the first portion 256a, and extends in a direction to depart from the speaker 241. That is, the second portion 256b and the third portion 256c are separately located on both sides of the first portion 256a.

As shown in FIG. 24 to FIG. 27, the second portion 256b is formed into a plate shape substantially parallel with, for example, the bottom wall 211. The second portion 256b faces the first support portion 251 and the first fixing portion 253 in a direction intersecting with the bottom wall 211 (e.g., in a direction intersecting substantially at right angles with the bottom wall 211). The second portion 256b is provided with a first tilted portion 261 (first attachment portion, first engaging portion).

The first tilted portion 261 engages with the first support portion 251. The first tilted portion 261 is, for example, a hole (round hole, through-hole, insertion hole) through which the first support portion 251 is passed. The first tilted portion 261 is not limited to the hole, and may be a recess (valley) provided in the holder 256. The first tilted portion 261 is engaged with (attached to, passed through) the first support portion 251 from a direction intersecting with the bottom wall 211. The first tilted portion 261 is engaged with the first support portion 251, for example, from a direction substantially parallel with the attachment surface 243a. The first tilted portion 261 is engaged with the first support portion 251, and the first support portion 251 thereby supports the speaker module 257.

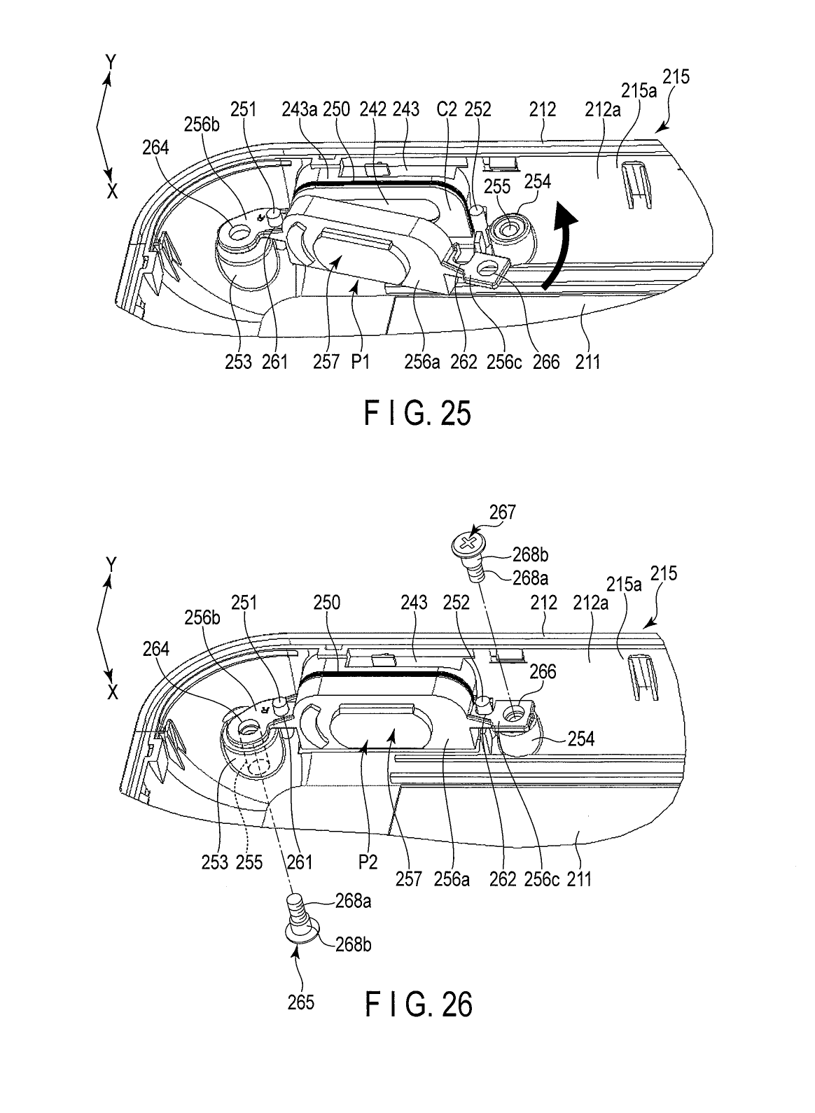

As shown in FIG. 25 and FIG. 26, the speaker module 257 can rotate on the first support portion 251 (center, rotational center, supporting point) between a first position P1 and a second position P2 while being supported by the first support portion 251.

As shown in FIG. 25, the first position P1 (temporary fixing position, temporary storage position) is a position distant from the sidewall 212. At the first position P1, the speaker module 257 is directed to intersect with the sidewall 212, and is tilted relative to the sidewall 212. At the first position P1, the speaker module 257 is distant from the sealing portion 250. A clearance C2 is provided between the speaker module 257 and the sealing portion 250. At the first position P1, the sealing portion 250 is not compressed.

The speaker module 257 can move to the second position P2 (main fixing position) from the first position P1 while being supported by the first support portion 251. In the present embodiment, the speaker module 257 is rotated on the first support portion 251 while the first tilted portion 261 is engaged with the first support portion 251, and the speaker module 257 is thereby moved to the second position P2 from the first position P1 in a direction substantially parallel with the bottom wall 211.

As shown in FIG. 26, the second position P2 is located closer to the sidewall 212 (the opening 242, the sealing portion 250) than the first position P1. At the second position P2, the speaker module 257 is located substantially parallel with the sidewall 212. The speaker module 257 is located in front of the opening 242, and faces the opening 242.

The sealing portion 250 is held between the speaker module 257 and the sidewall 212 while the speaker module 257 moves from the first position P1 to the second position P2. At the second position P2, the speaker module 257 abuts on the sealing portion 250, and presses the sealing portion 250 to the sidewall 212. As a result, the sealing portion 250 is compressed (compressively deformed) between the speaker module 257 and the sidewall 212, and liquid-tightly closes the space between the speaker module 257 and the sidewall 212. The sealing portion 250 liquid-tightly closes around the opening 242.

As shown in FIG. 24 to FIG. 27, the third portion 256c is formed into a plate shape substantially parallel with, for example, the bottom wall 211. The third portion 256c faces the second fixing portion 254 in a direction intersecting with the bottom wall 211 (e.g., in a direction intersecting substantially at right angles with the bottom wall 211). The third portion 256c is provided with a second engagement portion 262 (second attachment portion, second engaging portion).

The second engagement portion 262 abuts on (engages with) the second support portion 252 at the second position P2. Thus, the rotation of the speaker module 257 is regulated at the second position P2, and the speaker module 257 is positioned at the second position P2. The second support portion 252 is an example of a “positioning portion”.

The speaker module 257 (the second portion 256b) has an end facing the second support portion 252. The second engagement portion 262 is provided at this end. One example of the second engagement portion 262 is a U-shaped cutout open toward the second support portion 252. The second engagement portion 262 engages with the second support portion 252 (the second support portion 252 is inserted into the second engagement portion 262) in a direction intersecting with the thickness direction of the housing 204 (e.g., in a direction substantially parallel to the bottom wall 211).

One example of the second engagement portion 262 has, for example, a hook 263 (claw portion, engaging portion, temporary fastening portion) which hooks to (catches) the second support portion 252. The second engagement portion 262 (the hook 263) engages with the second support portion 252 at the second position P2, and is temporarily fixed to the second support portion 252. The speaker module 257 is thereby temporarily fixed at the second position P2. The second engagement portion 262 may be temporarily fixed to, for example, the second support portion 252 having a narrow portion (engaging portion, temporary fastening portion) smaller in diameter than the second support portion 252, instead of the hook 263.

As shown in FIG. 24 to FIG. 27, a second portion 262b of the holder 256 has a first hole 264 (first insertion hole, first through-hole, first fixing hole, first bore, first attachment hole). The first hole 264 faces the hole 255 of the first fixing portion 253 at the second position P2. A first fixing member 265 (first fixing portion, first attachment member, first support member) is attached to the first hole 264 of the holder 256 and the hole 255 of the first fixing portion 253.

The first fixing member 265 is, for example, a screw. The first fixing member 265 is inserted into the first hole 264 and the hole 255 of the first fixing portion 253 from a direction intersecting with the bottom wall 211 (e.g., from a direction intersecting substantially at right angles with the bottom wall 211). The first fixing member 265 is inserted into the first hole 264 and the hole 255 of the first fixing portion 253, for example, from a direction substantially parallel with the attachment surface 243a.

In the present embodiment, the inner surface of the mask 216 has a third fixing portion 269 (see FIG. 19 and FIG. 20) facing the first fixing portion 253. The third fixing portion 269 has a threaded hole 255. As shown in FIG. 26, the first fixing member 265 is passed through, for example, the hole 255 (insertion hole) of the first fixing portion 253 and the first hole 264 of the holder 256 from the outside of the housing 204, and fixed to (engaged with, threaded into) the hole 255 of the third fixing portion 269 of the mask 216. As a result, the speaker module 257 is fixed to the housing 204 at the second position P2.

Instead of the configuration described above, the hole 255 of the first fixing portion 253 may be a threaded hole. The first fixing member 265 may be passed through the first hole 264 of the holder 256 from the inside of the housing 204, and fixed to (engaged with, threaded into) the hole 255 of the first fixing portion 253.

As shown in FIG. 24 to FIG. 27, the third portion 256c of the holder 256 has a second hole 266 (second insertion hole, second through-hole, second fixing hole, second bore, second attachment hole). The second hole 266 faces the hole 255 of the second fixing portion 254 at the second position P2. A second fixing member 267 (second fixing portion, second attachment member, second support member) is attached to the second hole 266 of the holder 256 and the hole 255 of the second fixing portion 254.

The second fixing member 267 is, for example, a screw. The second fixing member 267 is inserted into the second hole 266 and the hole 255 of the second fixing portion 254 from a direction intersecting with the bottom wall 211 (e.g., from a direction intersecting substantially at right angles with the bottom wall 211). The second fixing member 267 is inserted into the second hole 266 and the hole 255 of the second fixing portion 254, for example, from a direction substantially parallel with the attachment surface 243a.

In the present embodiment, the hole 255 of the second fixing portion 254 is a threaded hole. The second fixing member 267 is passed through the second hole 266 of the holder 256 from the inside of the housing 204, and fixed to (engaged with, threaded into) the hole 255 of the second fixing portion 254. As a result, the speaker module 257 is fixed to the housing 204 at the second position P2.

As shown in FIG. 26, in the present embodiment, the first fixing member 265 and the second fixing member 267 are stepped screws. The stepped screw has a threaded portion 268a and an unthreaded portion 268b (trunk portion, cylinder portion). The unthreaded portion 268b is not threaded. Therefore, the unthreaded portion 268b has a smaller component tolerance than the threaded portion 268a.

The unthreaded portion 268b of the first fixing member 265 is inserted into the first hole 264 of the holder 256. The unthreaded portion 268b of the second fixing member 267 is inserted into the second hole 266 of the holder 256. The position of the holder 256 is precisely determined by the insertion of the unthreaded portions 268b of the first and second fixing members 265 and 267 into the holes 264 and 266. Thus, the compression amount (crush amount) of the sealing member 217 can be accurately controlled.

The speaker module 257 is temporarily stored (temporarily fixed) at the first position P1 of the housing 204, and fixed (mainly fixed) to the housing 204 at the second position P2 to which the speaker module 257 is moved from the first position P1. Referring now to FIG. 25, FIG. 26, and FIG. 27, one example of how to attach the speaker module 257 is described.

First, the sealing portion 250 is attached to the sidewall 212 before the attachment of the speaker module 257 (S1 in FIG. 27). The sealing portion 250 may be attached to the speaker module 257 instead of the sidewall 212.

Here, a first direction X and a second direction Y based on a viewpoint different from that described above are defined. The first direction X is a direction intersecting with the bottom wall 211. In the present embodiment, the first direction X is a direction substantially perpendicular to the bottom wall 211. The first direction X may be a direction diagonally intersecting with the bottom wall 211.

As shown in FIG. 25, the speaker module 257 is attached to the first support portion 251 from the first direction X (S2 in FIG. 27). The speaker module 257 is attached at the first position P1 distant from the sidewall 212 without abutting on the sealing portion 250 attached to the sidewall 212 (without removing the sealing portion 250). The speaker module 257 is supported by the first support portion 251 at the first position P1.

The speaker module 257 is moved to the second position P2 from the first position P1 while being supported by the first support portion 251 (S3 in FIG. 27). In the present embodiment, the speaker module 257 is rotated on the first support portion 251 in the second direction Y. The second direction Y is a direction intersecting with the first direction X. The second direction Y is a direction to approach the sealing portion 250 (the sidewall 212) from the first position P1. In the present embodiment, the second direction Y is a direction substantially parallel with the bottom wall 211. The second direction Y is a direction intersecting with (e.g., a direction intersecting substantially at right angles with) the sealing portion 250 (the sidewall 212).

The sealing portion 250 is held between the speaker module 257 and the sidewall 212 while the speaker module 257 moves from the first position P1 to the second position P2 (S4 in FIG. 27), and the sealing portion 250 is compressed between the speaker module 257 and the sidewall 212. This liquid-tightly closes around the opening 242.

When the speaker module 257 is moved to the second position P2, the second engagement portion 262 abuts on the second support portion 252, and the movement of the speaker module 257 is regulated (S5 in FIG. 27). The speaker module 257 is thereby positioned at the second position P2. In the present embodiment, the second engagement portion 262 has the hook 263 which hooks to the second support portion 252. Thus, the speaker module 257 which has been moved to the second position P2 is engaged with the second support portion 252 at the second position, and held at the second position P2.

The second fixing member 267 is then passed through the second hole 266 of the holder 256, and engaged with the hole 255 of the second fixing portion 254 (S6 in FIG. 27). The speaker module 257 is thereby fixed (mainly fixed) to the housing 204. Moreover, in the present embodiment, after the base 215 and the mask 216 are set to each other, the first fixing member 265 is passed through the hole 255 of the first fixing portion 253 and the first hole 264 of the holder 256, and engaged with the hole 255 of the third fixing portion 269 of the mask 216. As a result, the base 215, the mask 216, and the speaker module 257 are fastened together.

According to such a configuration, the assembly of the television receiver 201 can be improved.

For example, when the sound release opening of the speaker is provided in the same surface as the display screen, the design is limited by the sound release opening, which makes it difficult to obtain, for example, an electronic apparatus having a narrow frame. Accordingly, the sound release opening may be provided in the sidewall of the housing, and the speaker may be attached to the inner surface of the sidewall.

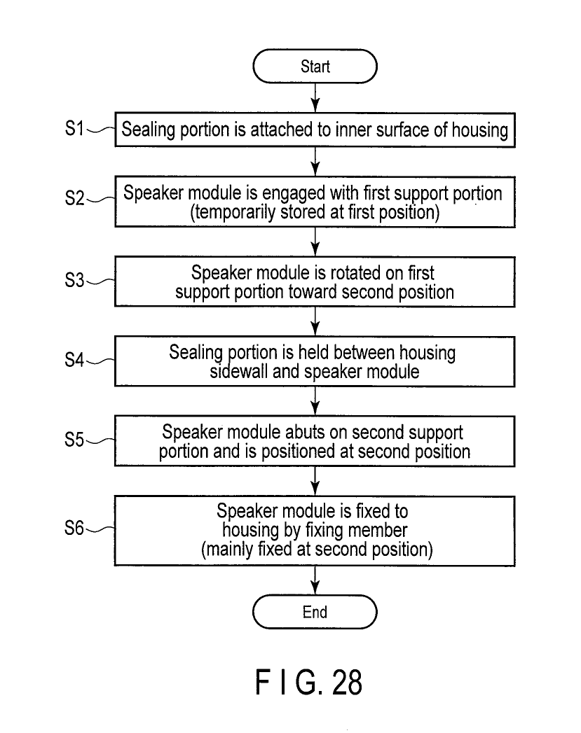

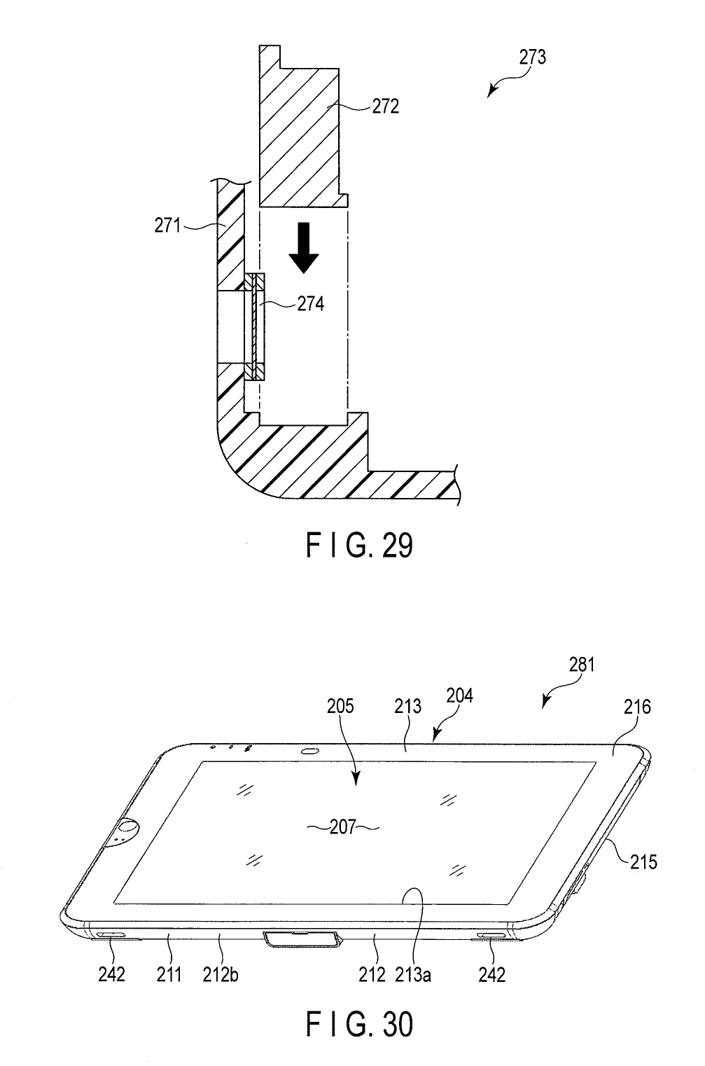

For comparison, an electronic apparatus 273 to which a speaker module 272 is attached from a direction substantially parallel with a sidewall 271 is shown in FIG. 28. The electronic apparatus 273 has a sealing portion 274 which is compressed between the sidewall 271 and the speaker module 272. In this case, if the speaker module 272 is attached from a direction substantially parallel with the sidewall 271, the speaker module 272 is caught by the end of the sealing portion 274, and the sealing portion 274 may be detached from the sidewall 271 or may be tilted and compressed. Thus, the assembly of the electronic apparatus 273 having such a configuration tends to deteriorate.

On the other hand, in the present embodiment, the television receiver 201 has the housing 204 and the speaker module 257. The speaker module 257 is temporarily stored at the first position P1 of the housing 204, and is fixed to the housing 204 at the second position P2 to which the speaker module 257 is moved from the first position P1. According to such a configuration, the attachment includes two steps, so that various problems are solved and the assembly of the television receiver 201 can be improved.

For example, in the present embodiment, the television receiver 201 has the sealing portion 250 which is held between the speaker module 257 and the sidewall 212 while the speaker module 257 is moved from the second position P2 to the first position P1. According to such a configuration, the sealing portion 250 is easily pressed from a proper direction, and the detachment or twisting of the sealing portion 250 can be inhibited. This makes it possible to improve the assembly of the television receiver 201.

In the present embodiment, the speaker module 257 is engaged with the first support portion 251 from the first direction X, and moved from the first position P1 to the second position P2 in the second direction Y intersecting with the first direction X. According to such a configuration, the direction in which the speaker module 257 presses the sealing portion 250 can be different from the direction in which the speaker module 257 is attached to the housing 204. Therefore, the speaker module 257 can be attached to the first support portion 251, for example, from a direction intersecting with the bottom wall 211. This makes it possible to improve the assembly of the television receiver 201.

In the present embodiment, the fixing members 265 and 267 are further provided. The fixing members 265 and 267 are attached to the housing 204 after the movement of the speaker module 257 to the second position P2, and fix the speaker module 257 at the second position P2. According to such a configuration, the speaker module 257 can be more firmly fixed at the second position P2.

In the present embodiment, the fixing member 267 is attached to the housing 204 from a direction intersecting with the bottom wall 211. According to such a configuration, the fixing member 267 can be attached to the housing 204, for example, from a direction intersecting with the bottom wall 211. This makes it possible to further improve the assembly of the television receiver 201.

In the present embodiment, the first support portion 251 is a first protrusion projecting in a direction intersecting with the bottom wall 211. The speaker module 257 is provided with the first tilted portion 261 with which the first protrusion engages. The speaker module 257 is rotated on the first protrusion while the first tilted portion 261 is engaged with the first protrusion. The speaker module 257 is thereby moved from the first position P1 to the second position P2 in a direction substantially parallel with the bottom wall 211. According to such a configuration, the speaker module 257 can be stably moved in a direction substantially parallel with the bottom wall 211. This makes it possible to further improve the assembly of the television receiver 201.

In the present embodiment, the housing 204 has a positioning portion (e.g., the second support portion 252). The speaker module 257 is provided with the second engagement portion 262 which is engaged with and temporarily fixed to the positioning portion at the second position P2. According to such a configuration, the position of the speaker module 257 is precisely determined at the second position. This makes it possible to further improve the assembly of the television receiver 201.

In the present embodiment, the positioning portion is a second protrusion projecting in a direction intersecting with the bottom wall 211. The second engagement portion 262 is a cutout which is provided at the end of the speaker module 257 facing the second protrusion and which is open toward the second protrusion. According to such a configuration, the speaker module 257 which has been rotated and moved to the second position P2 easily engages with the positioning portion. This makes it possible to further improve the assembly of the television receiver 201.

The present embodiment is also applicable to, for example, an electronic apparatus 281 shown in FIG. 30. The electronic apparatus 281 is, for example, a slate PC. As described above, the present embodiment and the following embodiments are widely applicable to various kinds of electronic apparatuses.

In the present embodiment, the attachment structure for the speaker has been described. The component to which the attachment structure according to the present embodiment is not limited to the speaker. The structure described above is widely applicable to various kinds of components including, for example, a connector, a camera, a switch, an LED, a microphone, and a receiver.

Although the components are attached to the sidewall 212 in the present embodiment described above, the attachment structure according to the present embodiment is not limited thereto. The attachment structure described above is also applicable to the attachment of the components to the bottom wall 211, the upper wall 213, or other parts. The movement direction of the component from the first position P1 to the second position P2 is not limited to the direction substantially parallel with the bottom wall 211. The movement of the component from the first position P1 to the second position P2 is not limited to the rotational movement, and may be a sliding movement or other kinds of movement. Moreover, the second support portion 252 can be omitted.

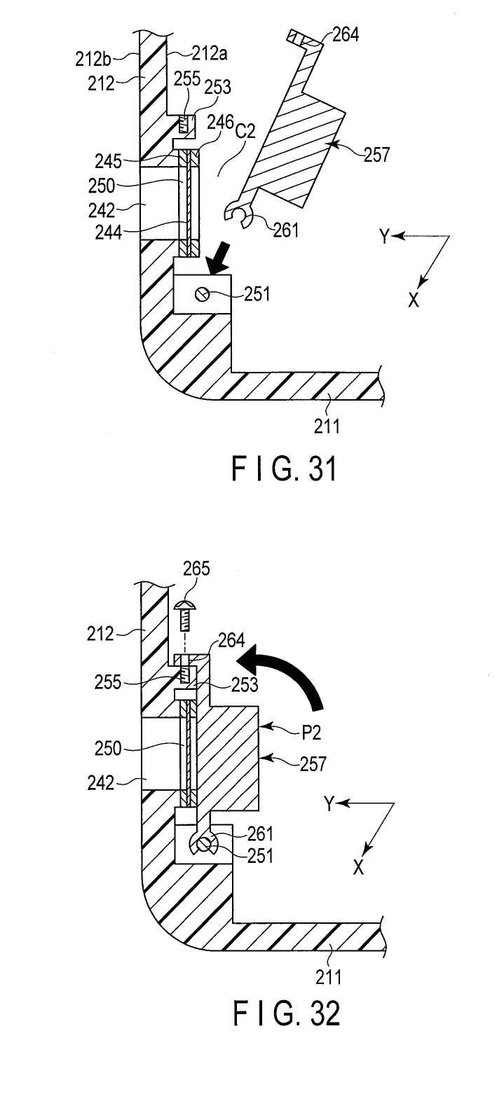

Referring now to FIG. 31 and FIG. 32, a seventh embodiment is described. As shown in FIG. 31, a support portion 251 and a fixing portion 253 are provided in a housing 204. The support portion 251 is, for example, a columnar pin projecting in a direction substantially parallel with a bottom wall 211. A speaker module 257 is provided with a tilted portion 261 and a hole 264. The speaker module 257 is attached to the support portion 251 from the first direction X intersecting with the bottom wall 211. The speaker module 257 is supported by the support portion 251 at the first position P1 distant from a sidewall 212.

As shown in FIG. 32, the speaker module 257 is moved from the first position P1 to the second position P2 while the tilted portion 261 is supported by the support portion 251. In the present embodiment, the speaker module 257 is rotated on the support portion 251 while the first tilted portion 261 is supported by the support portion 251, and the speaker module 257 is thereby moved to the second position P2 from the first position P1. The speaker module 257 is moved to the second position P2 from the first position P1 in the second direction Y intersecting with the first direction X.

A sealing portion 250 is held and compressed between the speaker module 257 and the sidewall 212 while the speaker module 257 moves from the first position P1 to the second position P2. The fixing member 265 fixes the speaker module 257 at the second position P2. A first fixing member 265 is attached to the housing 204 from a direction intersecting with the bottom wall 211 (e.g., in a direction substantially parallel with the sidewall 212).

According to such a configuration, the assembly of a television receiver 201 can be improved as in the sixth embodiment described above.

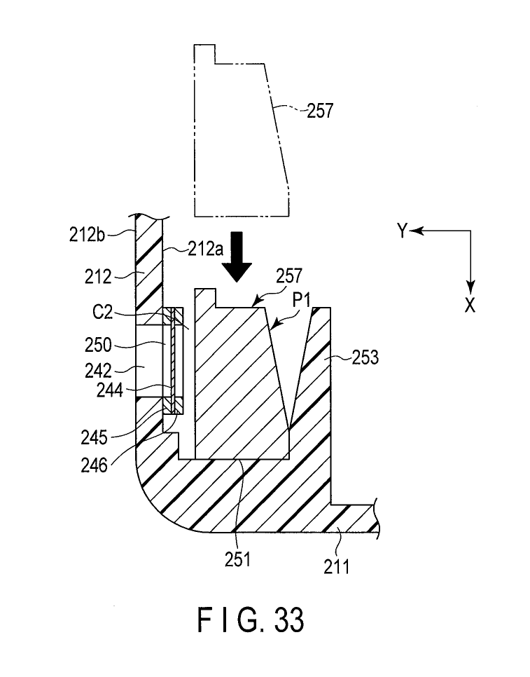

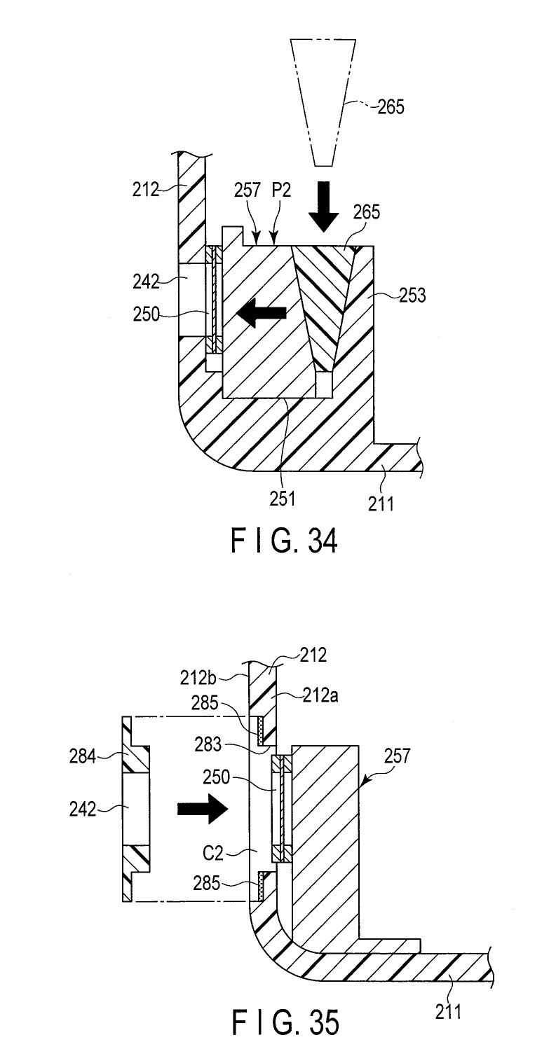

Referring now to FIG. 33 and FIG. 34, an eighth embodiment is described. As shown in FIG. 33, a support portion 251 is provided in a housing 204. The support portion 251 according to the present embodiment is a mounting surface (attachment surface, temporary storage position, sliding surface, guide) provided in the housing 204. A speaker module 257 is placed on the mounting surface and thereby supported by the support portion 251. The speaker module 257 is placed on the support portion 251 from the first direction X intersecting with a bottom wall 211. The speaker module 257 is supported by the support portion 251 at the first position P1 distant from a sidewall 212.

As shown in FIG. 34, the speaker module 257 is moved to the second position P2 from the first position P1 while being supported by the support portion 251. In the present embodiment, the speaker module 257 is mounted on the support portion 251, and in this condition, slid and moved from the first position P1 to the second position P2 (to the sidewall 212).

In the present embodiment, a fixing member 265 is attached to, for example, the rear of the speaker module 257. The fixing member 265 is attached to the housing 204 from a direction intersecting with the bottom wall 211 (e.g., in a direction substantially parallel with the sidewall 212). The fixing member 265 is, for example, wedge-shaped. As a result of the attachment of the fixing member 265, the speaker module 257 is pressed to the sidewall 212, and moved to the second position P2. The fixing member 265 fixes the speaker module 257 at the second position P2.

According to such a configuration, the assembly of a television receiver 201 can be improved as in the sixth embodiment described above.

Referring now to FIG. 35, a ninth embodiment is described. As shown in FIG. 35, a sidewall 212 is provided with a first opening 283 and a lid 284. The lid 284 is removably attached to the sidewall 212, and covers the first opening 283. The lid 284 is fixed to the sidewall 212, for example, by a waterproof double-sided tape 285. The lid 284 is provided with a second opening 242 (sound release portion, sound release opening). The lid 284 is a part of the sidewall 212.

A sealing portion 250 is attached to a speaker module 257. The speaker module 257 is attached to the inside of a housing 204. The lid 284 is attached to the sidewall 212 after the attachment of the speaker module 257. As a result of the attachment of the lid 284 to the sidewall 212, the sealing portion 250 is held and compressed between the lid 284 and the speaker module 257.

According to such a configuration, the detachment or tilting of the sealing portion 250 can be inhibited. This makes it possible to improve the assembly of the television receiver 201.

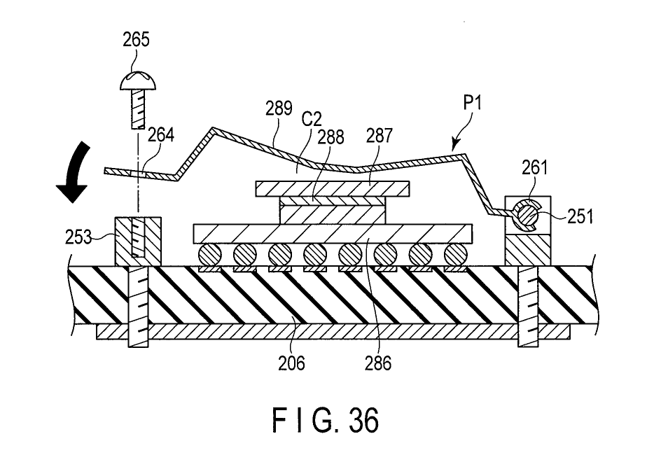

Referring now to FIG. 36, a tenth embodiment is described. In the sixth to ninth embodiments, the component attachment structures for waterproofing have been described. The attachment structures described above are not exclusively intended for waterproofing, and are applicable to various purposes. In the present embodiment, the attachment structure described above is applied to, for example, a pressing component for a heating component.

As shown in FIG. 36, a circuit board 206 has a heating component 286. The heating component 286 is, but is not limited to, for example, a CPU or a graphic chip. A heat receiving component 287 (or a heat release component 287) is attached to the heating component 286. A heat conducting member 288 (heat transfer member) intervenes between the heating component 286 and the heat receiving component 287. The heat conducting member 288 is, for example, a heat conducting sheet or a heat conducting grease. The heat conducting member 288 is an example of an elastic portion.

A television receiver 201 has a press member 289 (press portion, press component). The heat receiving component 287 is located between the heating component 286 and the press member 289. The press member 289 presses the heat receiving component 287 to the heating component 286. The heat conducting member 288 is held between the heat receiving component 287 and the heating component 286. This allows firm thermal connection between the heating component 286 and the heat receiving component 287.

As shown in FIG. 36, the circuit board 206 is provided with a support portion 251 and a fixing portion 253. The support portion 251 is, for example, a columnar pin projecting substantially parallel with the circuit board 206. The fixing portion 253 is, for example, a stud provided in the circuit board 206. The press member 289 is provided with a tilted portion 261 and a hole 264.

The press member 289 is supported by the support portion 251 at the first position P1 distant from the heat receiving component 287. The press member 289 is moved from the first position P1 to the second position P2 to approach the heat receiving component 287 while the first tilted portion 261 is supported by the support portion 251. In the present embodiment, the press member 289 is rotated on the support portion 251 while the tilted portion 261 is supported by the support portion 251, and the press member 289 is thereby moved from the first position P1 to the second position P2.

The heat conducting member 288 is held and compressed between the heat receiving component 287 and the heating component 286 (i.e., the press member 289 and the heating component 286) while the press member 289 moves from the first position P1 to the second position P2. The fixing member 265 fixes the press member 289 at the second position P2.

According to such a configuration, the assembly of a television receiver 201 can be improved as in the sixth embodiment described above. Moreover, according to the present embodiment, the number of fixing members such as screws can be reduced. This contributes to the cost reduction of the television receiver 201.

The attachment structures according to the sixth to tenth embodiments do not exclusively hold the sealing portion 250 and the heat conducting member 288. For example, the embodiments are also applicable to a structure which holds a conductive member against electromagnetic interference (EMI) between a connector and a conducting portion of the housing 204.

According to at least one of the electronic apparatuses described above, at least a part of a first member is located between a wall portion and a substrate, and a second member covers an opening and is pressed to the wall portion by the first member, so that the degree of freedom in the designing is higher.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing comprising
a bottom wall,
a sidewall comprising an opening, at least a part of the sidewall extending in a direction intersecting with the bottom wall, and
a substrate facing at least a part of the bottom wall;
a support member being at least partly located between the sidewall and the substrate, the support member facing the sidewall and comprising an insertion portion;
a water infiltration inhibitor comprising a contact portion and a displacement portion and configured to block the opening, the contact portion configured to abut the sidewall to cover the opening and being between the sidewall and the support member, the displacement portion configured to be elastically deformable in the insertion portion;
an operation portion configured to be inserted through the opening and configured to abut the displacement portion;
a fixing portion in the housing, the fixing portion configured to fix the support member to press the water infiltration inhibitor to the sidewall;
an engaging portion in the housing, the engaging portion configured to engage with the support member so that the support member is movable in a direction intersecting with the sidewall; and
an electronic component on the substrate and facing the displacement portion, the electronic component configured to be operated when pressed by the elastically deformed displacement portion.

2. An electronic apparatus comprising:
a housing comprising
a wall portion comprising a first opening, and
a substrate;
a first member being at least partly located between the wall portion and the substrate and facing the wall portion;
a second member between the wall portion and the first member, the second member configured to abut the wall portion to cover the first opening and configured to block the first opening, at least a part of the second member configured to be elastically deformable;
a fixing portion in the housing, the fixing portion configured to fix the first member to press the second member to the wall portion; and
a first electronic component on the substrate configured to be operated when pressed by the elastically deformed part of the second member.

3. The electronic apparatus of claim 2, wherein the substrate intersects with the wall portion.

4. The electronic apparatus of claim 2, further comprising a third member configured to be inserted through the first opening and configured to be elastically deformable, the third member facing a part of the second member.

5. The electronic apparatus of claim 3, further comprising a third member configured to be inserted through the first opening and configured to be elastically deformable, the third member facing a part of the second member.

6. The electronic apparatus of claim 2, wherein the first member comprising an insertion portion into which a part of the second member configured to be elastically deformable is inserted, and
wherein the first electronic component faces the part of the second member.

7. The electronic apparatus of claim 5, wherein the first member comprising an insertion portion into which a part of the second member configured to be elastically deformable is inserted, and
wherein the first electronic component faces the part of the second member.

8. The electronic apparatus of claim 2, wherein the fixing portion comprises a pair of fit portions, the fit portions each comprising a base portion and a claw portion, the base portion projecting from the wall portion, the claw portion extending from the base portion in a direction along the wall portion, and
wherein the first member and the second member are held between the wall portion and the claw portion.

9. The electronic apparatus of claim 7, wherein the fixing portion comprises a pair of fit portions, the fit portions each comprising a base portion and a claw portion, the base portion projecting from the wall portion, the claw portion extending from the base portion in a direction along the wall portion, and
wherein the first member and the second member are held between the wall portion and the claw portion.

10. The electronic apparatus of claim 2, further comprising an engagement portion in the housing, the engagement portion configured to engage with the first member so that the first member is movable in a direction intersecting with the wall portion.

11. The electronic apparatus of claim 9, further comprising an engagement portion in the housing, the engagement portion configured to engage with the first member so that the first member is movable in a direction intersecting with the wall portion.

12. The electronic apparatus of claim 11, wherein the first member comprises a first portion configured to abut the second member, and a second portion intersecting with the first portion and configured to engage with the engagement portion.

13. The electronic apparatus of claim 12, wherein the engagement portion comprises a projecting portion projecting from the housing, and
wherein the first member further comprises a bore in the second portion, and the first member is configured to rotate on the projecting portion inserted through the bore.

14. The electronic apparatus of claim 2, further comprising:
a fourth member between the wall portion and the first member so that the fourth member abuts on the wall portion to cover a second opening in the wall portion and configured to watertightly close the second opening, at least a part of the fourth member configured to be elastically deformable; and
a second electronic component on the substrate configured to be operated by the elastically deformed part of the fourth member,
wherein the fixing portion configured to fix the first member to press the second member and the fourth member to the wall portion.

15. The electronic apparatus of claim 13, further comprising:
a fourth member between the wall portion and the first member so that the fourth member abuts on the wall portion to cover a second opening in the wall portion and configured to watertightly close the second opening, at least a part of the fourth member configured to be elastically deformable; and
a second electronic component on the substrate configured to be operated by the elastically deformed part of the fourth member,
wherein the fixing portion configured to fix the first member to press the second member and the fourth member to the wall portion.

16. The electronic apparatus of claim 2, wherein the housing comprises a bottom wall facing at least a part of the substrate, and
the wall portion intersects with the bottom wall.

17. The electronic apparatus of claim 15, wherein the housing comprises a bottom wall facing at least a part of the substrate, and
the wall portion intersects with the bottom wall.

18. An electronic apparatus comprising:
a housing comprising
a wall portion comprising an opening, and
a substrate;
a first member which is at least partly between the wall portion and the substrate;
a second member configured to cover the opening and pressed to the wall portion by the first member, at least a part of the second member configured to be elastically deformable; and
an electronic component on the substrate configured to be pushed by the deformed part of the second member.
